(19) United States
(12) Patent Application Publication
(10) Pub. No.: US 2026/0032907 A1
(43) Pub. Date: Jan. 29, 2026

(54) MANAGING CONNECTING STRUCTURES IN SEMICONDUCTOR DEVICES

(71) Applicant: Yangtze Memory Technologies Co., Ltd., Wuhan (CN)

(72) Inventors: Jiandong WANG, Wuhan (CN); Xiaofen ZHENG, Wuhan (CN); Yuping XIA, Wuhan (CN)

(21) Appl. No.: 18/891,198

(22) Filed: Sep. 20, 2024

Related U.S. Application Data
(63) Continuation of application No. PCT/CN2024/107564, filed on Jul. 25, 2024.

(51) Int. Cl. H10B 43/27

(52) U.S. Cl. CPC H10B 43/27

(57) ABSTRACT

The present disclosure relates to methods, devices, systems, and techniques for managing connecting structures in semiconductor devices. An example semiconductor device includes a first stack of conductive layers and isolating layers alternating with each other along a first direction and a second stack of dielectric layers and isolating layers alternating with each other along the first direction. The semiconductor device further includes an isolating wall between the first stack and the second stack along a second direction perpendicular to the first direction. The isolating wall includes first isolating structures extending along the first direction and being spaced along a third direction perpendicular to the first direction and the second direction. The semiconductor device further includes contact structures extending through at least a part of the second stack along the first direction and connecting structures extending through the isolating wall along the second direction.

### CROSS-REFERENCE TO RELATED APPLICATIONS

This application is a continuation of International Application No. PCT/CN2024/107564, filed on Jul. 25, 2024, the disclosure of which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing connecting structures in semiconductor devices.

One aspect of the present disclosure features a semiconductor device. The semiconductor device includes a first stack of conductive layers and isolating layers alternating with each other along a first direction and a second stack of dielectric layers and isolating layers alternating with each other along the first direction. The semiconductor device further includes an isolating wall between the first stack and the second stack along a second direction perpendicular to the first direction. The isolating wall includes first isolating structures extending along the first direction and being spaced along a third direction perpendicular to the first direction and the second direction. The semiconductor device further includes contact structures extending through at least a part of the second stack along the first direction and connecting structures extending through the isolating wall along the second direction. A connecting structure of the connecting structures connects a contact structure of the contact structures to a conductive layer of the conductive layers of the first stack, and an isolating structure of the first isolating structures extends through the connecting structure along the first direction.

In some implementations, the semiconductor device further includes a gate line structure extending along the third direction. The first stack is between the gate line structure and the isolating wall along the second direction.

In some implementations, the semiconductor device further includes second isolating structures extending through the first stack along the first direction. At least one of the second isolating structures is adjacent to the connecting structure along the second direction.

In some implementations, the isolating wall further includes inner structures extending along the first direction and being spaced along the third direction. The inner structures and the first isolating structures alternate with each other along the third direction. The isolating wall further includes outer layers extending along the third direction and being spaced along the first direction. The inner structures and the first isolating structures extend through the outer layers along the first direction.

In some implementations, the inner structures include a dielectric material, and the outer layers include a semiconductor material.

In some implementations, the inner structures and the outer layers include a same dielectric material.

In some implementations, along the third direction, a first size of the connecting structure at a first location is smaller than a second size of the connecting structure at a second location, the first location being closer to a center of the isolating structure than the second location along the second direction.

In some implementations, the semiconductor device includes an array region and a connection region adjacent to the array region in the second direction, the second stack is in the connection region, and the semiconductor device includes an array of channel structures in the array region.

In some implementations, the semiconductor device includes a first semiconductor structure and a second semiconductor structure bonded together. The first semiconductor structure includes the first stack, the second stack, the isolating wall, the contact structures, and the connecting structure, and the second semiconductor structure includes a peripheral circuit coupled to the first semiconductor structure and configured to control the semiconductor device.

Another aspect of the present disclosure features a semiconductor device. The semiconductor device includes a first stack of conductive layers and isolating layers alternating with each other along a first direction and a second stack of dielectric layers and isolating layers alternating with each other along the first direction. The semiconductor device further includes an isolating wall between the first stack and the second stack along a second direction perpendicular to the first direction, contact structures extending through at least a part of the second stack along the first direction, and connecting structures extending through the isolating wall along the second direction. Along a third direction perpendicular to the first direction and the second direction, a first size of a connecting structure of the connecting structures at a first location is smaller than a second size of the connecting structure at a second location. The first location is closer to a center of the isolating wall than the second location along the second direction.

In some implementations, the connecting structure connects a contact structure of the contact structures to a conductive layer of the conductive layers of the first stack.

In some implementations, the isolating wall includes isolating structures extending along the first direction and being spaced along a third direction perpendicular to the first direction and the second direction. An isolating structure of the isolating structures extends through the connecting structure along the first direction.

In some implementations, the isolating wall further includes inner structures extending along the first direction and being spaced along the third direction. The inner structures and the isolating structures alternate with each other along the third direction. The isolating wall further includes outer layers extending along the third direction and being spaced along the first direction. The inner structures and the isolating structures extend through the outer layers along the first direction.

A further aspect of the present disclosure features a method of forming a semiconductor device. The method includes forming a first stack of conductive layers and isolating layers alternating with each other along a first direction and a second stack of dielectric layers and isolating layers alternating with each other along the first direction. The method further includes forming an isolating wall between the first stack and the second stack along a second direction perpendicular to the first direction. The isolating wall includes first isolating structures extending along the first direction and being spaced along a third direction perpendicular to the first direction and the second direction. The method further includes forming contact structures extending through at least a part of the second stack along the first direction and forming connecting structures extending through the isolating wall along the second direction. Forming the connecting structures includes forming a connecting structure of the connecting structures that connects a contact structure of the contact structures to a conductive layer of the conductive layers of the first stack. An isolating structure of the first isolating structures extends through the connecting structure along the first direction.

In some implementations, the method further includes forming a stack of dielectric layers and isolating layers alternating with each other along the first direction and forming an array of channel holes, isolating holes, first dummy channel holes, second dummy channel holes, and gate line holes extending through the stack of dielectric layers and isolating layers along the first direction by a same etching process. The array of channel holes is in an array region of the semiconductor device, the isolating holes, the first dummy channel holes, and the second dummy channel holes are in a connection region of the semiconductor device, and the gate line holes include gate line holes in the array region and gate line holes in the connection region. The isolating holes and the first dummy channel holes are arranged along a line extending in the third direction. One of the first dummy channel holes is between two adjacent isolating holes of the isolating holes along the third direction. The second dummy channel holes are arranged along a line extending in the third direction. The gate line holes are arranged along a line extending in the third direction. The second dummy channel holes are between the gate line holes and the first dummy channel holes along the second direction. The method further includes forming an array of channel structures in the array of channel holes, first isolating structures in the first dummy channel holes, and second isolating structures in the second dummy channel holes.

In some implementations, the method further includes forming inner holes by expanding and connecting the isolating holes. The inner holes and the first isolating structures alternate with each other along the third direction. The method further includes forming tunnels between the isolating layers of the stack by removing a portion of the dielectric layers of the stack exposed by the inner holes. The tunnels extend along the third direction, and the inner holes and the first isolating structures extend through the tunnels along the first direction.

In some implementations, forming the isolating wall includes forming outer layers of the isolating wall by depositing a semiconductor material in the tunnels and forming inner structures of the isolating wall by depositing a dielectric material into the inner holes. The method further includes forming a gate line space by expanding the gate line holes. The gate line space includes the expanded gate line holes connected with each other along the third direction.

In some implementations, forming the first stack of conductive layers and isolating layers and the second stack of dielectric layers and isolating layers includes replacing the dielectric layers of the stack in the array region and the dielectric layers of the stack in the connection region between the gate line space and the isolating wall with conductive layers. The first stack includes the conductive layers and the isolating layers in the array region and the conductive layers and the isolating layers in the connection region between the gate line space and the isolating wall, the second stack includes a remaining portion of the dielectric layers of the stack and the isolating layers of the stack in the connection region, and the conductive layer of the conductive layers of the first stack is surrounded by a liner layer.

In some implementations, the method further includes forming a gate line structure by filling the gate line space with the semiconductor material and forming a contact hole in the connection region. The contact hole extends into the second stack along the first direction and reaches a dielectric layer of the dielectric layers of the second stack, the contact hole is aligned with the isolating structure along the second direction, and an outer layer of the outer layers of the isolating wall is in contact with the dielectric layer and the conductive layer along the second direction. The method further includes forming a first space in the dielectric layer by removing a portion of the dielectric layer that is in contact with the contact hole to expose the outer layer, forming a second space by removing a portion of the outer layer to expose the liner layer in contact with the conductive layer along the second direction, and expanding the second space by removing a portion of the liner layer to expose the conductive layer.

In some implementations, forming the connecting structure includes forming the connecting structure in the first space and the second space by depositing a conductive material into the first space and the second space through the contact hole. Forming the contact structure includes forming a first layer of the contact structure by depositing the conductive material on an inner surface of the contact hole and forming a second layer of the contact structure by filling the contact hole with a dielectric material.

### BRIEF DESCRIPTION OF DRAWINGS

FIGS. 1A-1D illustrate an example semiconductor device.

FIGS. 2A-2B illustrate another example semiconductor device.

FIGS. 3A(1)-3T(2) illustrate an example process of manufacturing a semiconductor device.

FIG. 4 illustrates a flow chart of an example process of manufacturing a semiconductor device.

FIG. 5 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher density, a memory device (e.g., a 3D NAND flash memory) can be formed to have a large number of layers and a high aspect ratio. For example, the memory device can have multiple decks, and each deck can have multiple layers. Conductive layer filling and connections between contact structures and conductive layers are important steps in the manufacturing process of memory devices. The large number of layers and the high aspect ratio of such memory devices may bring challenges to the manufacturing process. For example, to improve the quality and reliability of the conductive layers, the conductive layer filling can be performed in separate processes (e.g., gate line loops in an array region and a connection region are carried out separately), and multiple sacrificial layers filling and removing steps can be involved in these processes, thereby increasing the fabrication complexity and reducing the processing window. In another example, a connection between a conductive layer and a contact structure may cause a loss of a high-K dielectric material of a liner layer between the conductive layer and adjacent isolating layers. That is, the uniformity of a structure of the conductive layer is affected, thereby reducing a breakdown voltage between the conductive layer and adjacent conductive layers. Therefore, contact structures and fabrication methods that can solve the aforementioned issues are desirable.

In one or more implementations of the present disclosure, an example semiconductor device is provided. The semiconductor device includes a first stack of alternating conductive layers and isolating layers and a second stack of alternating dielectric layers and isolating layers. The semiconductor device further includes an isolating wall between the first stack and the second stack. The isolating wall includes isolating structures extending along a vertical direction and being spaced along a first horizontal direction. The semiconductor device further includes contact structures extending through at least a part of the second stack along the vertical direction and connecting structures extending through the isolating wall along a second horizontal direction.

Implementations of the present disclosure can provide one or more of the following technical advantages and/or benefits. First, in the example semiconductor device described above, the sacrificial layer removal step can stop on the isolating wall, and a subsequent poly removal step can stop on the high-K dielectric material of the liner layer. By applying etchants with different selection ratios in the sacrificial layer removal step, the poly removal step, and the high-K removal step, the high-K loss issue can be solved, and reliable connection structures can be formed. Second, a process to remove the isolating wall and fill a dielectric material can be added to create an isolation structure between the conductive layers. Third, the described techniques can reduce a number of fabrication loops to form conductive layers and contact structures and avoid multiple sacrificial layers filling and removing steps, thereby improving the product yield and reducing the fabrication costs.

The techniques can be applied to any semiconductor structures or devices that are configured to avoid electric leakage or breakdown, e.g., between conductive layers or components. The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

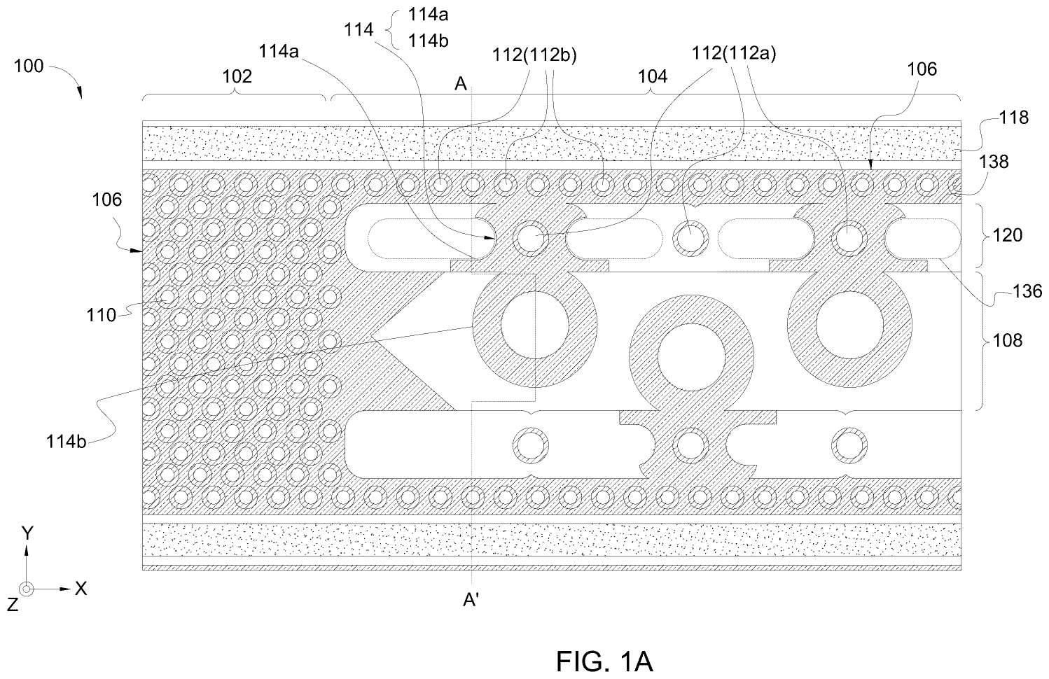

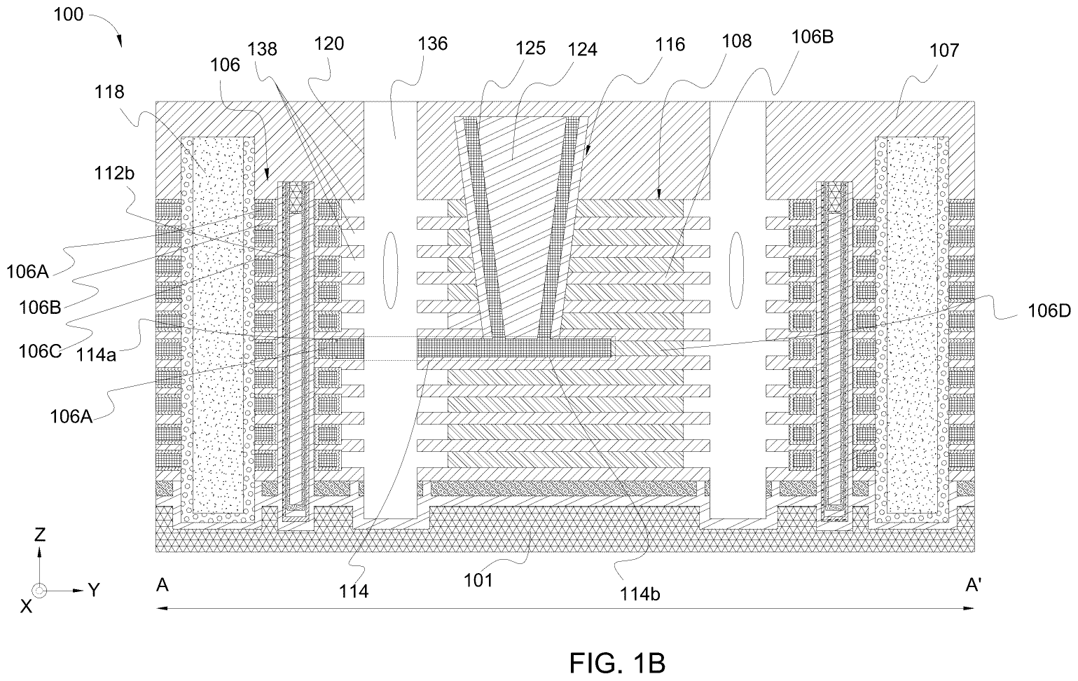

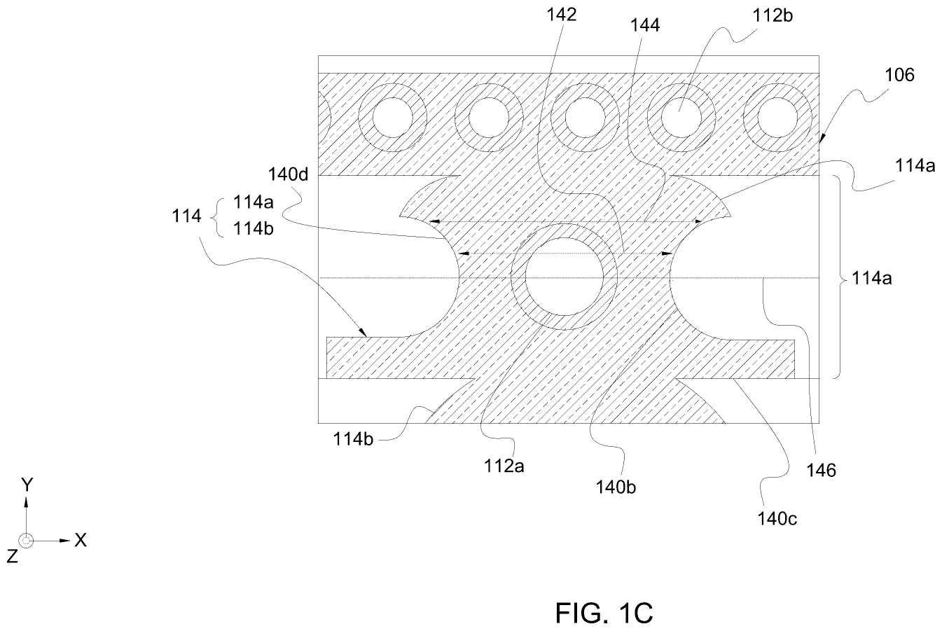

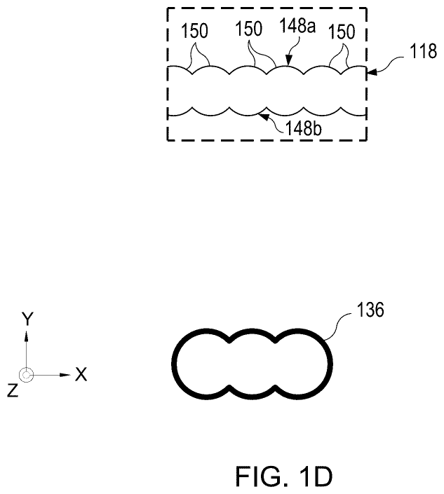

It is noted that X, Y, and Z axes (also referred to as X, Y, and Z directions) are included in FIGS. 1A-1D to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a top view of an example semiconductor device 100. In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1A, the semiconductor device 100 includes an array region 102 and a connection region 104 adjacent to the array region 102 along a first horizontal direction (e.g., the X direction). It is understood that the example in FIG. 1A is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction.

The semiconductor device 100 includes a stack 106 of alternating conductive layers and isolating layers (e.g., conductive layers 106A and isolating layers 106B as shown in FIG. 1B). In some implementations, a part of the stack 106 can be in the array region 102, and another part of the stack 106 can be in the connection region 104. The semiconductor device 100 further includes a stack 108 of alternating dielectric layers and isolating layers (e.g., dielectric layers 106D and isolating layers 106B as shown in FIG. 1B). In some implementations, the stack 108 can be in the connection region 104. The stack 106 is connected to the stack 108.

The semiconductor device 100 can include one or more gate line structures 118. Each gate line structure 118 can extend in the X direction. The gate line structure 118 can extend into both the array region 102 and the connection region 104. In some implementations, the gate line structures 118 can divide an array region into multiple memory blocks. In some implementations, the gate line structure 118 can function as a common source contact for channel structures 110 in the array region 102.

The semiconductor device 100 can include isolating walls 120. The isolating walls 120 can be in the connection region 104. Each isolating wall 120 can separate the stack 106 (e.g., the portion of the stack 106 in the connection region 104) from the stack 108 along a second horizontal direction (e.g., the Y direction) perpendicular to the first horizontal direction (e.g., the X direction). The portion of the stack 106 in the connection region 104 can be between an adjacent gate line structure 118 and an adjacent isolating wall 120 along the Y direction. The isolating wall 120 can include inner structures 136 and outer layers 138. The inner structures 136 can extend along a vertical direction (e.g., the Z direction) perpendicular to the first horizontal direction (e.g., the X direction) and the second horizontal direction (e.g., the Y direction). The outer layers 138 can extend in a plane (e.g., the X-Y plane) perpendicular to the Z direction. The inner structures 136 can be spaced along the X direction.

The semiconductor device 100 can include contact structures 116 and connecting structures 114 in the connection region 104. The connecting structures 114 can extend through the isolating wall 120 along the Y direction. In some implementations, one of the conductive layers 106A of the stack 106 is coupled to a control circuit through a corresponding connecting structure 114 and a corresponding contact structure 116. For example, each contact structure 116 can extend through at least a part of the stack 108 along the Z direction and is connected to a corresponding connecting structure of the connecting structures 114. The corresponding connecting structure 114 is further connected to a corresponding conductive layer 106A of the stack 106 in the connection region 104. As shown in FIG. 1A, each connecting structure 114 can include a portion 114a and a portion 114b. The portion 114a is between the stack 106 and the stack 108 in the connection region 104 along the Y direction and extends through the isolating wall 120 along the Y direction. The portion 114a is connected to the conductive layer 106A along the Y direction. The portion 114b is connected to the contact structure 116 along the Z direction (as shown in FIG. 1B). Details of the portion 114a of the connecting structure 114 will be described below with reference to FIG. 1C.

The semiconductor device 100 can include an array of channel structures 110 extending through the stack 106 in the array region 102. Each channel structure 110 can be used to form a string of memory cells coupled in serial along the vertical direction (e.g., the Z direction). In some implementations, the semiconductor device 100 can include isolating structure 112 for process variation control during fabrication and/or for additional mechanical support. In some instances, the isolating structures can also be referred to as dummy channel structures or dummy memory strings. The isolating structures 112 can include isolating structures 112a extending along the Z direction in the isolating walls 120 and isolating structures 112b extending through the stack 106 in the connection region 104 along the Z direction. In some implementations, the isolating structures or dummy channel structures 112 can be in one or more dummy regions or peripheral regions (not shown in FIG. 1A). The isolating structures 112a in an isolating wall 120 can be spaced along the X direction. As shown in FIG. 1A, the inner structures 136 and the isolating structures 112a in the same isolating wall 120 can alternate with each other along the X direction. In some implementations, an isolating structure 112a can extend through a corresponding connecting structure 114 along the Z direction. In some implementations, at least one of the isolating structures 112b is adjacent to a corresponding connecting structure 114 along the Y direction.

Each channel structure 110 can be in the shape of a cylinder or a pillar, and can include a high-K layer, a block layer surrounded by the high-K layer, a charge trapping layer (or a storage layer) surrounded by the block layer, a tunneling layer surrounded by the charge trapping layer, a channel layer surrounded by the tunneling layer, and a core filler layer surrounded by the channel layer, which extend through the conductive layers 106A and the isolating layers 106B of the stack 106 in the array region 102, and a channel contact formed above the core filler layer and being in contact with the channel layer. In some implementations, the channel layer can include silicon, such as amorphous silicon, polysilicon, or single crystalline silicon, the tunneling layer can include silicon oxide, silicon nitride, or any combination thereof, the blocking layer can include silicon oxide, silicon nitride, high-k dielectrics, or any combination thereof, and the charge trapping layer can include silicon nitride, silicon oxynitride, silicon, or any combination thereof. In some implementations, the tunneling layer, the charge trapping layer and the blocking layer, collectively referred to as a memory film, can include ONO dielectrics (silicon Oxide-silicon Nitride-silicon Oxide).

In some implementations, the isolating structure 112 and the channel structure 110 can have similar or the same structure and can be formed in the same manufacturing process. In some other implementations, the isolating structure 112 and the channel structure 110 can have different structures. For example, the isolating structure 112 can be a solid dielectric structure. In other words, the isolating structure 112 can be a continuous structure made of a dielectric material (e.g., silicon oxide).

FIG. 1B illustrates a cross-sectional view of the semiconductor device 100 along cut line AA′ of FIG. 1A. The semiconductor device 100 includes a substrate 101, the stack 106 of alternating conductive layers 106A and isolating layers 106B, and the stack 108 of alternating dielectric layers (also referred to as sacrificial layers) 106D and isolating layers 106B. Each isolating layer 106B can have a portion between two adjacent conductive layers 106A in the stack 106 and another portion between two adjacent dielectric layers 106D in the stack 108. The stack 106 and the stack 108 are provided over the substrate 101. The substrate 101 can be any suitable semiconductor substrate having any suitable semiconductor material, such as monocrystalline, polycrystalline or single crystalline semiconductor. For example, the substrate 101 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the substrate 101 can be removed from the semiconductor device 100 in a later process of manufacturing the semiconductor device 100. The semiconductor device 100 can include a top layer 107 made of an isolating material (e.g., oxide).

The stack 106 can extend in the second horizontal direction (e.g., the Y direction) that is parallel to a top surface of the substrate 101 and perpendicular to the first horizontal direction (e.g., the X direction). The conductive layers 106A and the isolating layers 106B can alternate in the vertical direction (e.g., Z direction) perpendicular to the second horizontal direction (e.g., the Y direction). The conductive layers 106A can be the same or different from each other in thickness, for example, ranging from 10-500 nm, e.g., about 35 nm. The isolating layers 106B can also be the same or different from each other in thickness, for example, ranging from 10-500 nm, e.g., about 25 nm. It should be noted that the number of the conductive layers 106A and the isolating layers 106B shown in FIG. 1B is for illustration only and that any suitable number of the conductive layers 106A and the isolating layers 106B can be included in the stack 106. The conductive layers 106A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The isolating layers 106B can include a dielectric material, such as silicon oxide, silicon nitride, silicon oxynitride, or any combination thereof. In some implementations, the isolating layers 106B can also include high-K dielectric materials, such as hafnium oxide, zirconium oxide, aluminum oxide, tantalum oxide, lanthanum oxide, or any combination thereof.

In some implementations, as illustrated in FIG. 1B, the stack 106 includes liner layers 106C. A liner layer 106C can cover part or all sides of a corresponding conductive layer 106A and be between the conductive layer 106A and two isolating layers 106B adjacent to the corresponding conductive layer 106A. The liner layer 106C can include a high-K dielectric material (e.g., Al₂O₃). In some examples, the conductive layer 106A includes a metallic material (e.g., W) and an adhesive material (e.g., TiN), and the adhesive material can be deposited between the metallic material and the high-K dielectric material. In some examples, the conductive layer 106A includes the metallic material (e.g., W), and the liner layer 106C includes the adhesive material (e.g., TiN) and the high-K dielectric material.

The stack 108 include dielectric layers 106D and isolating layers 106B alternating with each other along the vertical direction (e.g., Z direction). The stack 108 can be connected to the stack 106. The isolating layers 106B can extend into both the stack 106 and the stack 108 along the second horizontal direction (e.g., Y direction) in the connection region 104. A dielectric layer 106D in the stack 108 can extend to and be in contact with a corresponding conductive layer 106A (or a liner layer 106C surrounding the corresponding conductive layer 106A) in the stack 106. To fabricate the stack 106 and the stack 108, a series of alternating dielectric layers 106D and isolating layers 106B can be first formed. Then, dielectric layers 106D in a region of the stack 106 can be etched away, e.g., through an opening formed in the position of the gate line structure 118, while dielectric layers 106D in the stack 108 remain unchanged. Then, the liner layers 106C and the conductive layers 106A can be formed in replace of the dielectric layers 106D in the region of the stack 106 to form the stack 106.

The gate line structure 118 can extend through the stack 106 along the vertical direction (e.g., the Z direction). In some implementations, as shown in FIG. 1B, the gate line structure 118 can extend from the top layer 107 into the substrate 101 along the Z direction. The isolating structures 112 (e.g., 112a and 112b) also can extend through the stack 106 along the vertical direction (e.g., the Z direction). In some implementations, as shown in FIG. 1B, the isolating structures 112 can extend into the substrate 101 along the Z direction. The contact structure 116 can extend through at least a part of the stack 108 (e.g., a set of dielectric layers 106D and isolating layers 106B of the stack 108) along the Z direction. As shown in FIG. 1B, the contact structure 116 can include a first layer 124 and a second layer 125. The first layer 124 and the second layer 125 can extend along the Z direction. The second layer 125 can be surrounding and in contact with the first layer 124. The first layer 124 can include a dielectric material (e.g., silicon oxide). The second layer 125 can include a conductive material. In some implementations, the contact structure 116 can be surrounded by a contact spacer 126, and the contact spacer 126 can include a dielectric material (e.g., silicon oxide).

The second layer 125 of the contact structure 116 can be coupled to a corresponding conductive layer of the conductive layers 106A of the stack 106 through a corresponding connecting structure of the connecting structures 114. For example, as shown in FIG. 1B, the second layer 125 of the contact structure 116 can be connected to the corresponding connecting structure 114 along the Z direction. The corresponding connecting structure 114 can be connected to the corresponding conductive layer 106A along the Y direction. The portion 114a of the connecting structure 114 is connected to the conductive layer 106A along the Y direction. The portion 114b is connected to the contact structure 116 along the Z direction. The portion 114b is between two adjacent isolating layers 106B of the stack 108 along the Z direction. The connecting structures 114 can include a conductive material. In some implementations, both the second layer 125 of the contact structure 116 and the connecting structure 114 can include a same conductive material (e.g., W or TiN). In some other implementations, the second layer 125 of the contact structure 116 and the connecting structure 114 can include different conductive materials. For example, the second layer 125 of the contact structure 116 can include W, and the connecting structure 114 can include TiN.

As shown in FIG. 1B, the outer layers 138 of the isolating wall 120 can be spaced along the Z direction. Adjacent outer layers 138 can be separated by the isolating layer 106B in the stack 106 and the isolating layer 106B in the stack 108 along the Z direction. The inner structures 136 of the isolating wall 120 can extend through the outer layers 138 along the Z direction. The isolating structures 112a (not shown in FIG. 1B) can also extend through the outer layers 138 along the Z direction. In some implementations, the inner structures 136 and the outer layer 138 of the isolating wall 120 can include a same dielectric material (e.g., silicon oxide).

In some implementations, the semiconductor device 100 is a bonded chip that include a first semiconductor structure and a second semiconductor structure (not shown in FIGS. 1A-1B). The first semiconductor structure can be stacked over the second semiconductor structure (e.g., along the Z direction). The first and second semiconductor structures can be jointed at a bonding structure or a bonding layer (not shown) therebetween. In some implementations, the bonding structure is disposed between the first and second semiconductor structures as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. The first semiconductor structure can include the stack 106, the stack 108, the isolating walls 120, the contact structures 116, the connecting structures 114, the channel structures 110, and the isolating structures 112. The second semiconductor structure can include peripheral circuits coupled to the first semiconductor structure. The peripheral circuits can be configured to control components (e.g., the conductive layers 106A and the channel structures 110 as described above) of the first semiconductor structure. In some implementations, the peripheral circuits include a plurality of transistors (e.g., planar transistors and/or 3D transistors). Trench isolations (e.g., shallow trench isolations (STIs)) and doped regions (e.g., wells, sources, and drains of transistors) can be formed on or in the substrate as well. In some examples, the peripheral circuits are formed using complementary metal-oxide-semiconductor (CMOS) technology, and the second semiconductor structure can be formed on a semiconductor die referred to as a control die or a CMOS die.

FIG. 1C illustrate an enlarged top view of the connecting structure 114. The connecting structure 114 can include the portion 114a and the portion 114b connected along the Y direction. The portion 114a can have at least four sides 140a, 140b, 140c, and 140d. The side 140a is adjacent to the stack 106 in the connection region 104. The side 140c is in contact with the portion 114b. The sides 140b and 140d can be two concave surfaces that are curved inward. The sides 140b and 140d can be in contact with two adjacent inner structures 136 of the isolating wall 120 along the X direction. In other words, the sides 140b and 140d can form two back-to-back curved surfaces (e.g., half circles in the X-Y plane) disposed along the X direction. In some implementations, along the X direction, a first size of the portion 114a at a location 142 is smaller than a second size of the portion 114a at a location 144. The location 142 is closer to a center axis 146 of the isolating structure 112a than the location 144 along the Y direction. The isolating structure 112a extends through the connecting structure 114 along the Z direction. In some implementations, the center axis 146 of the isolating structure 112a can overlap with a center axis (e.g., extending along the X direction) of the isolating wall 120.

FIG. 1D illustrates an enlarged view of the gate line structure 118 and the inner structure 136 of FIGS. 1A-1B. As shown in FIG. 1D, the gate line structure 118 can have at least two non-flat surfaces 148a and 148b opposite to each other (e.g., along the Y direction). Each of the two surfaces 148a and 148b includes a series of curved portions connected together. For example, the surface 148a includes curved portions 150 connected with one another along the X direction. In other words, the surfaces 148a and 148b are wave-like or caterpillar-like. In some implementations, a cross section of the gate line structure 118 has a shape of partial circles arranged in a line and connected together. The cross section of the gate line structure 118 is in the X-Y plane (e.g., perpendicular to the vertical direction). Similarly, the inner structure 136 can also have a series of curved surfaces connected together. For example, a cross section (e.g., in the X-Y plane) of the inner structure 136 has a shape of partial circles arranged in a line and connected together. In other words, the surfaces of the inner structure 136 are also wave-like or caterpillar-like.

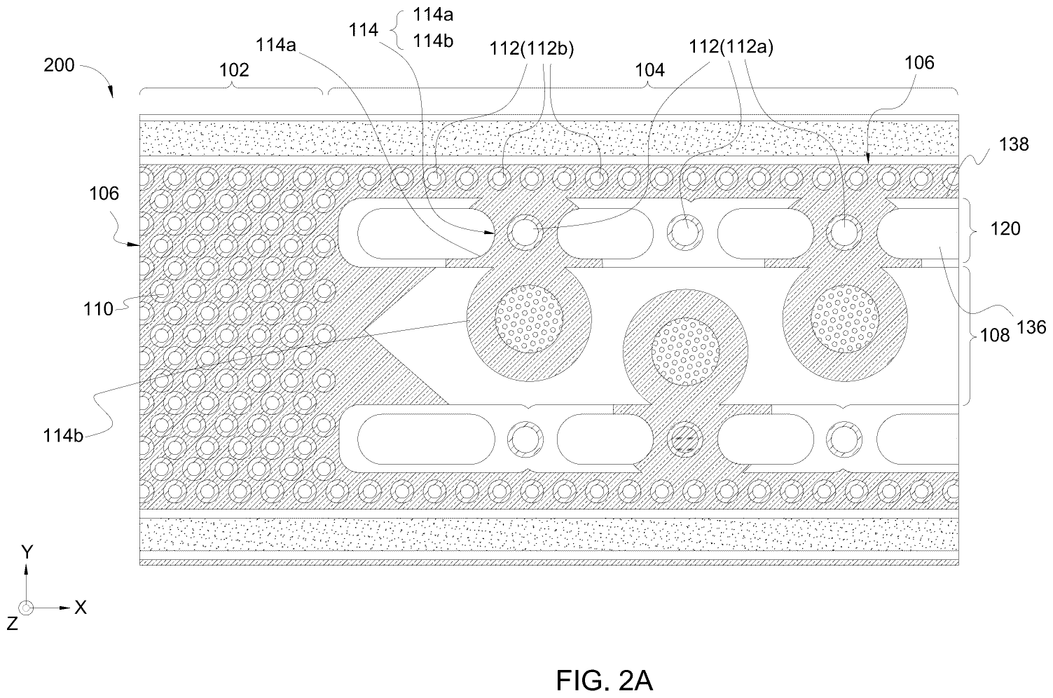

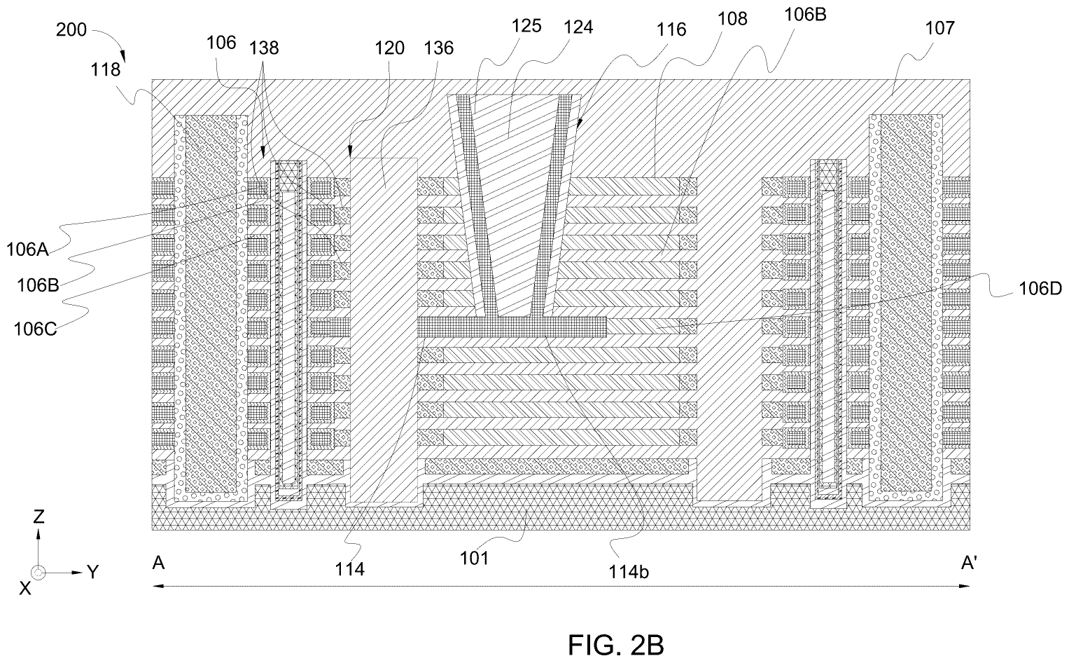

FIG. 2A illustrates a top view of another example semiconductor device 200. FIG. 2B illustrates a cross-sectional view of the semiconductor device 200 along a cut line at the same location of the cut line AA′ of FIG. 1A. The semiconductor device 200 can be similar to the semiconductor device 100 of FIGS. 1A-1D and can also include the stack 106, the stack 108, the channel structures 110, the isolating structures 112, the gate line structures 118, the isolating walls 120, and the connecting structures 114, etc. In some implementations, as shown in FIGS. 2A-2B, the outer layers 138 and the inner structures 136 of each isolating wall 120 can include different materials. For example, the inner structures 136 of the isolating wall 120 can include a dielectric material (e.g., silicon oxide), and the outer layers 138 of the isolating wall 120 can include a semiconductor material (e.g., polysilicon).

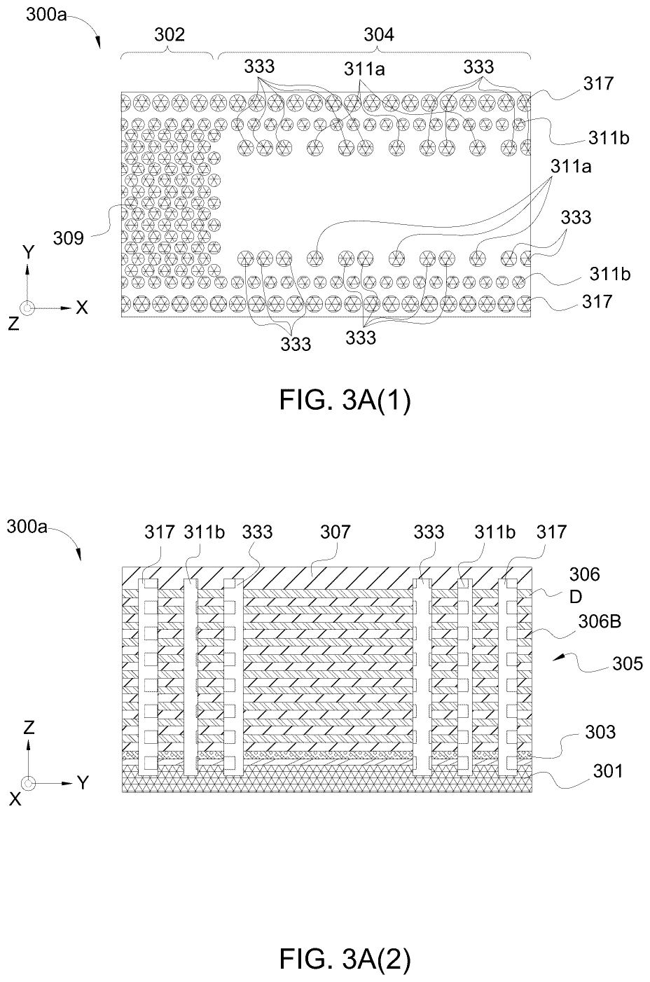

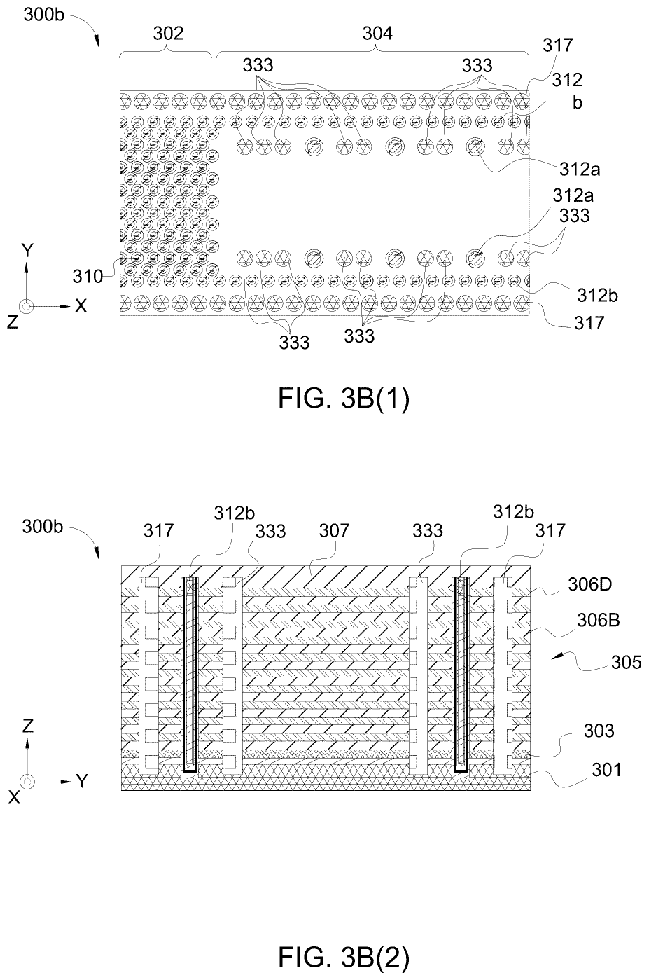

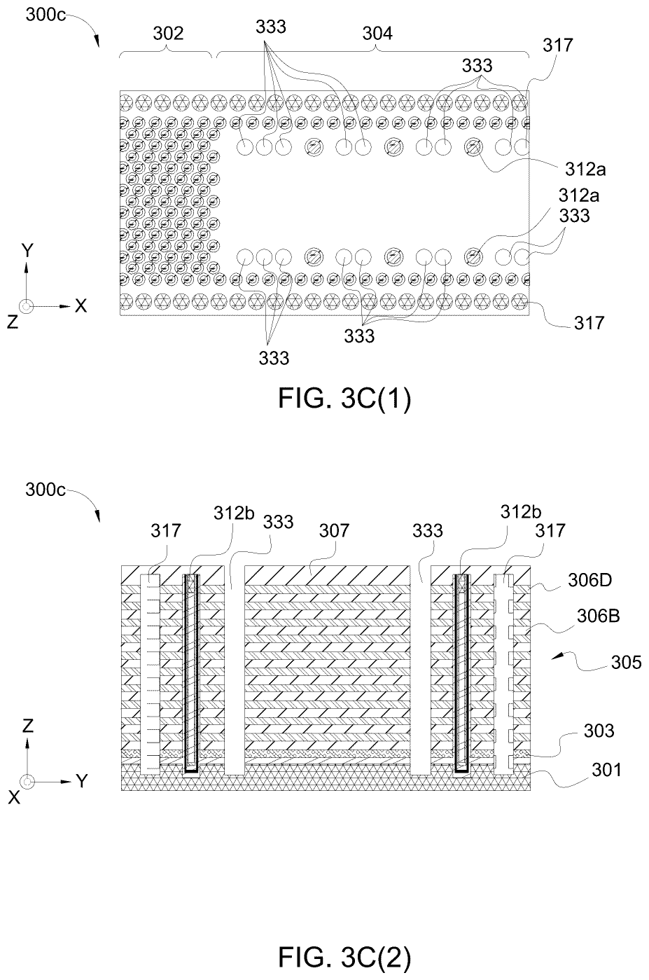

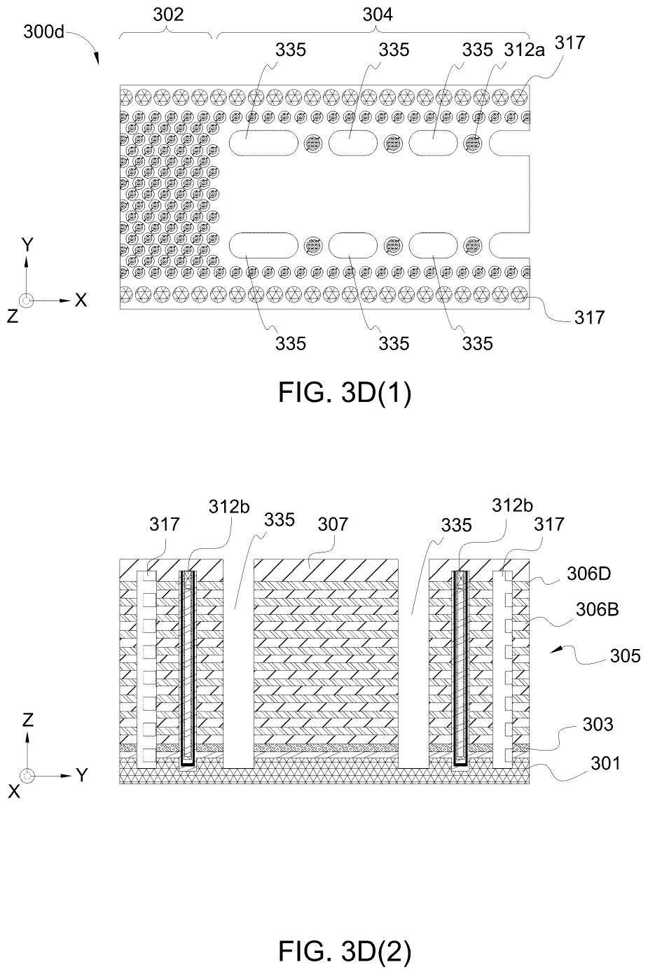

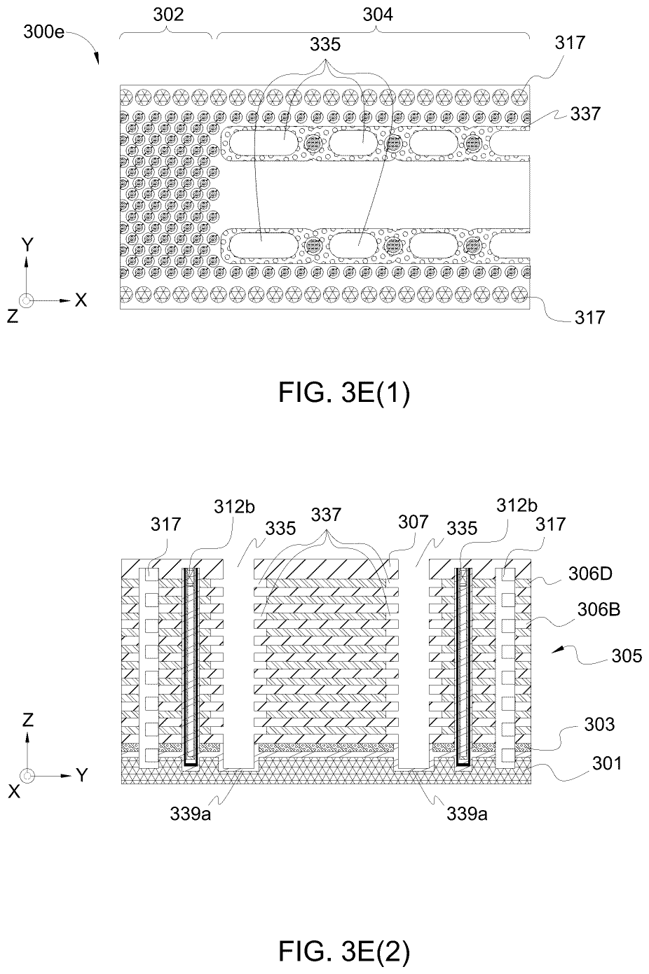

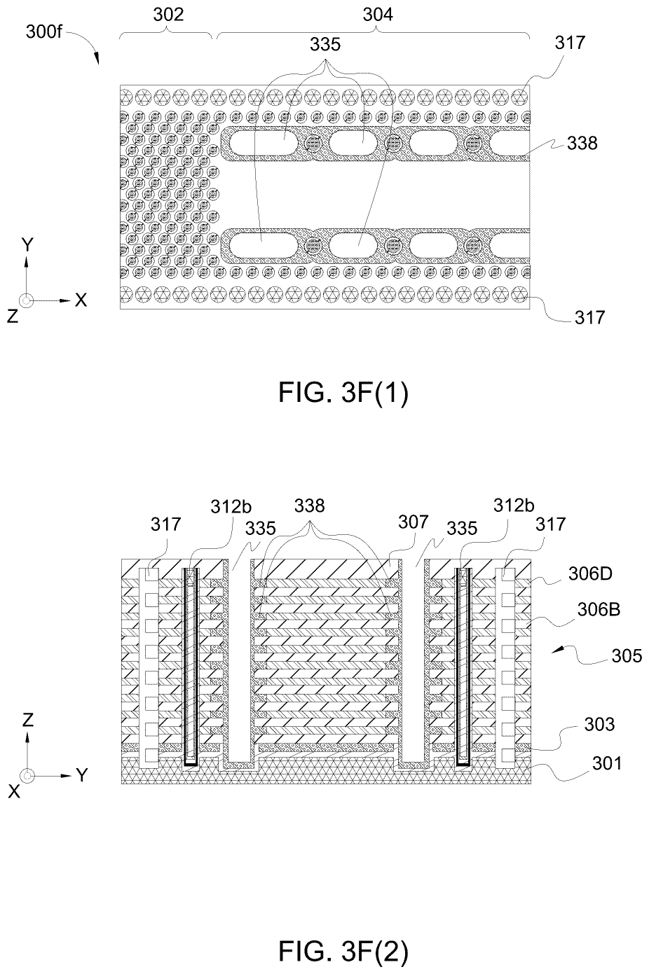

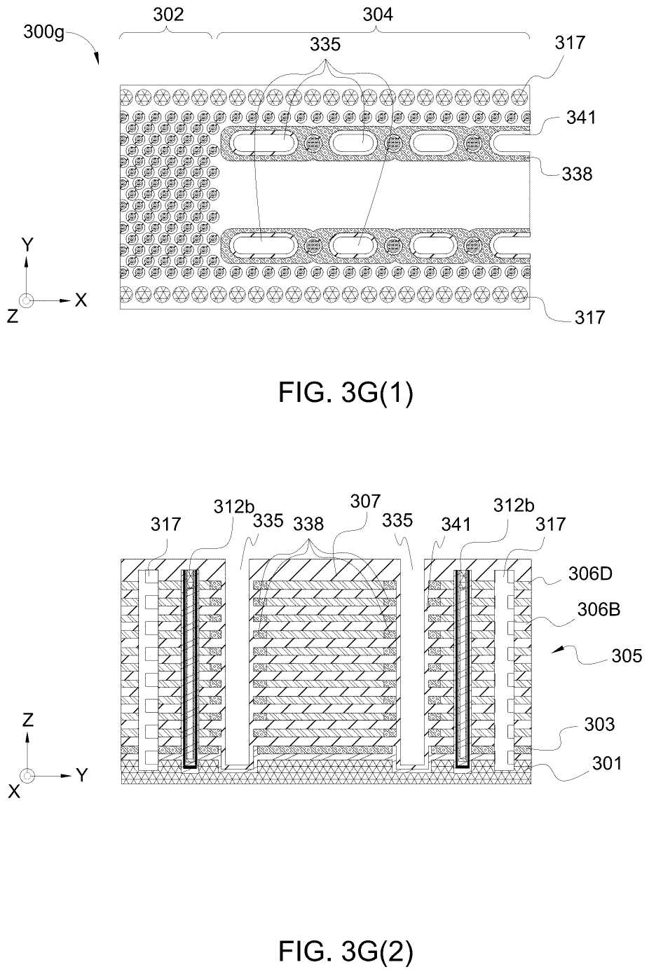

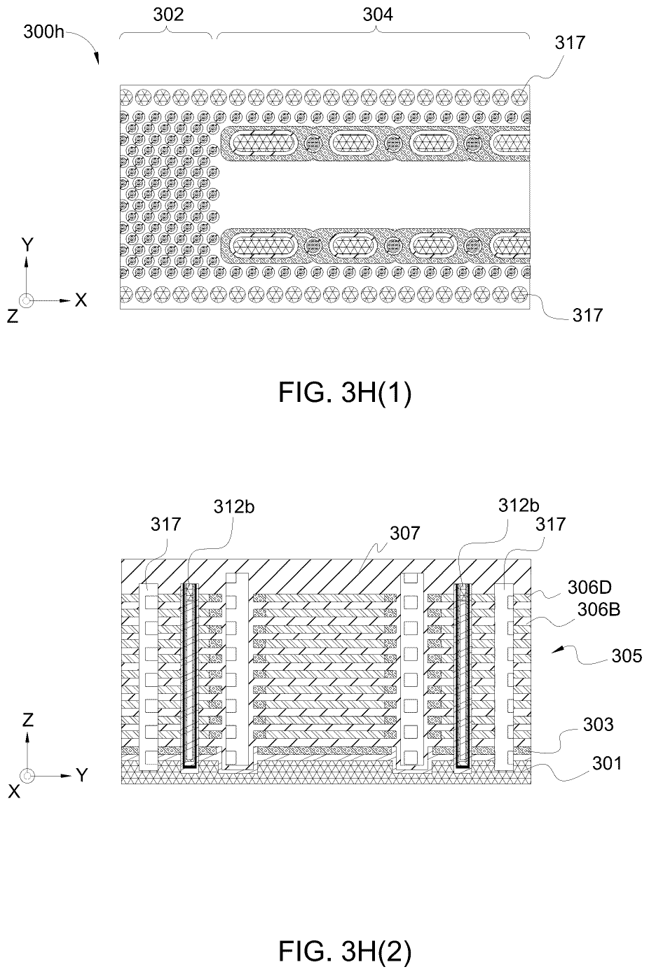

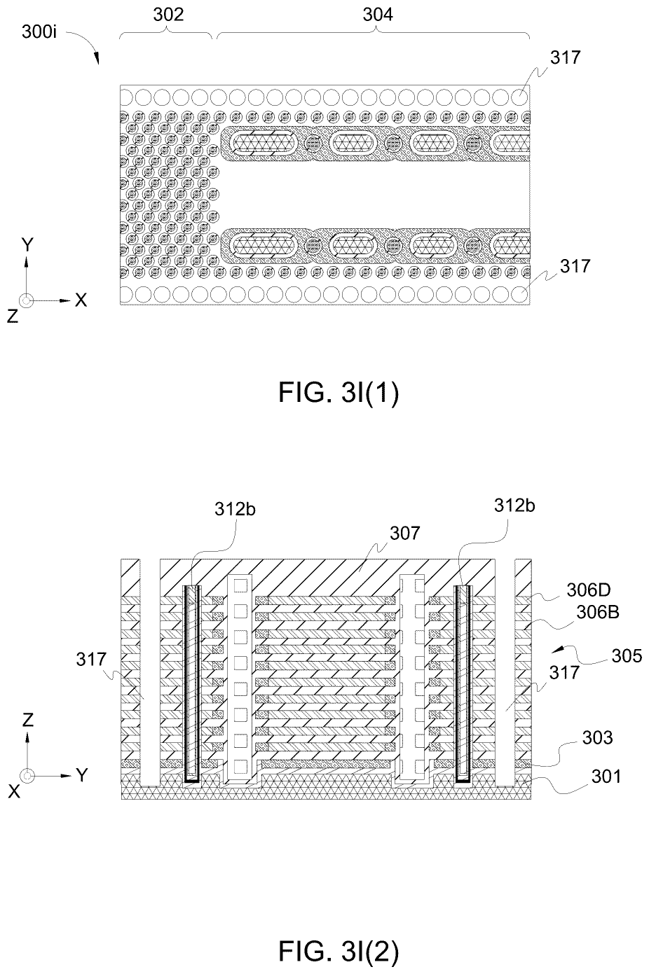

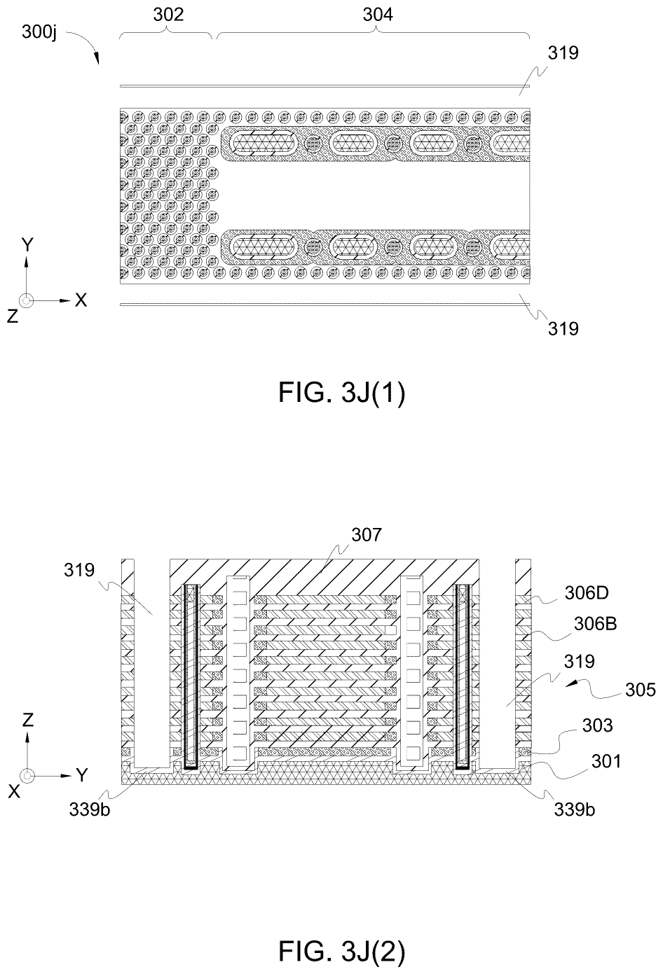

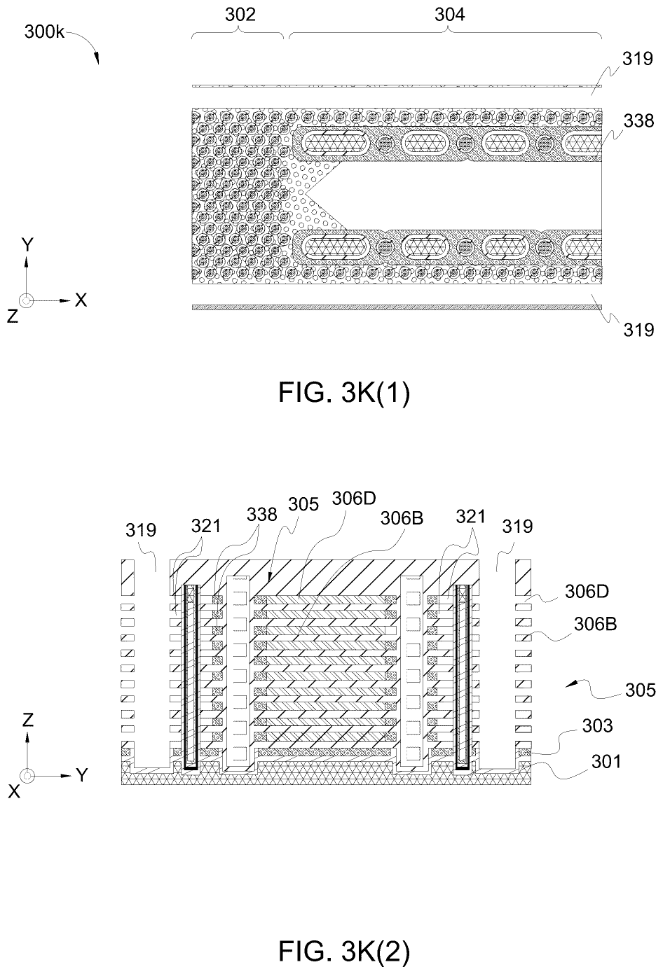

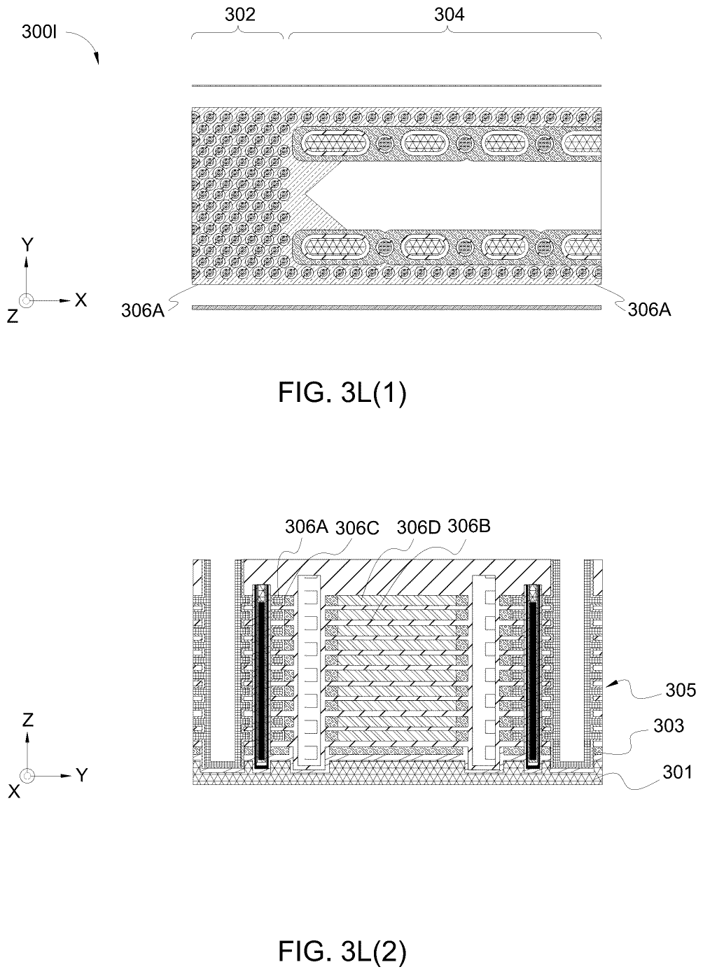

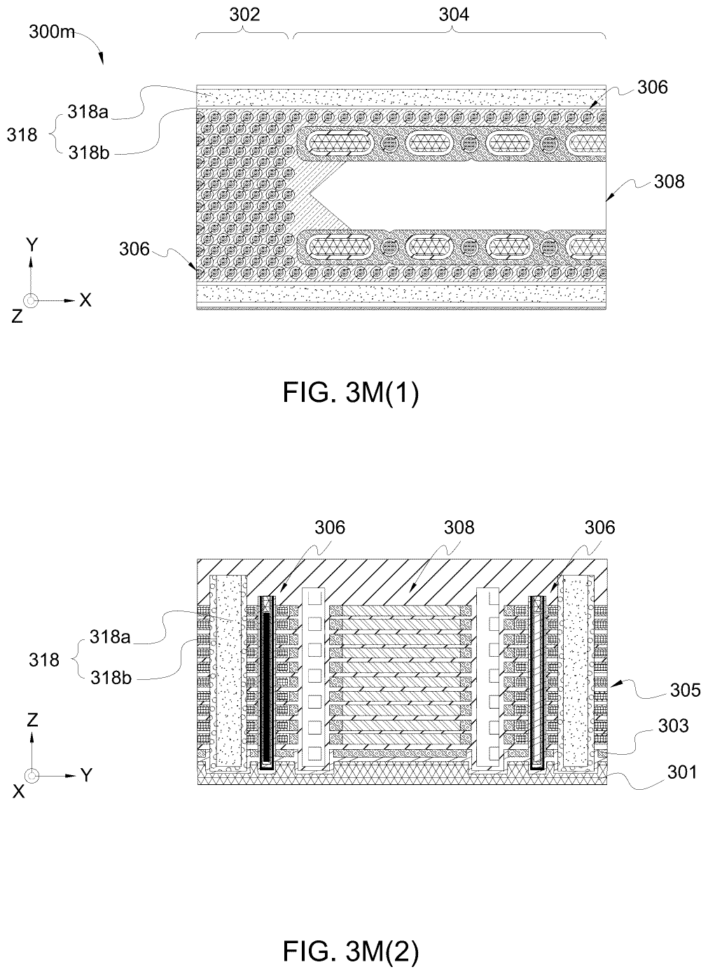

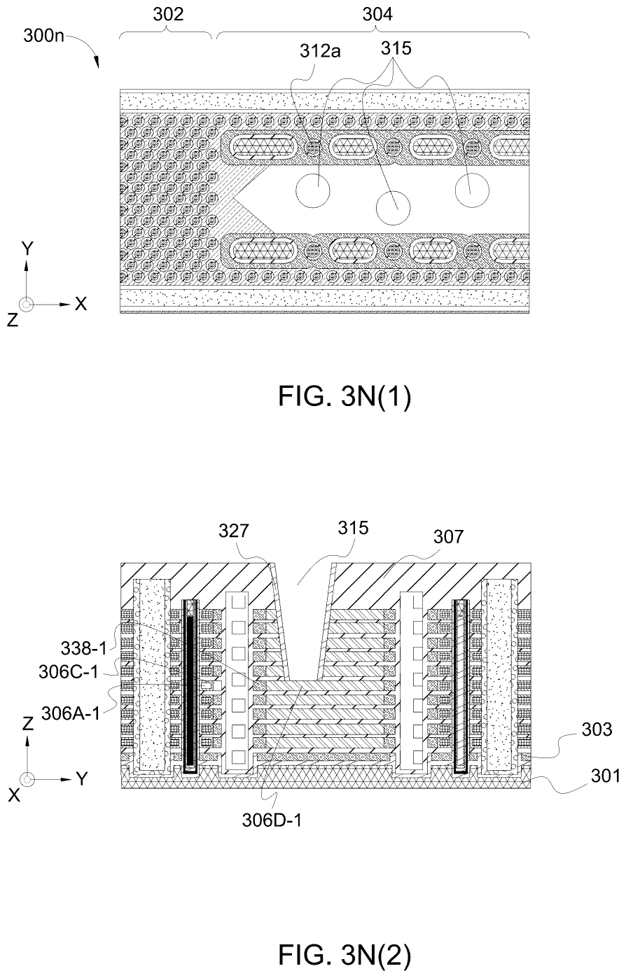

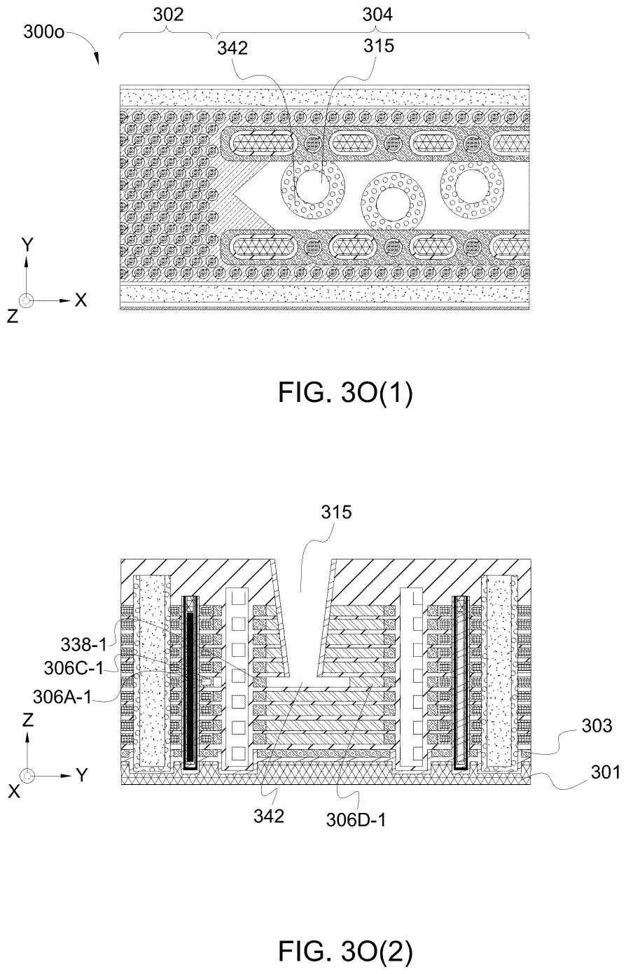

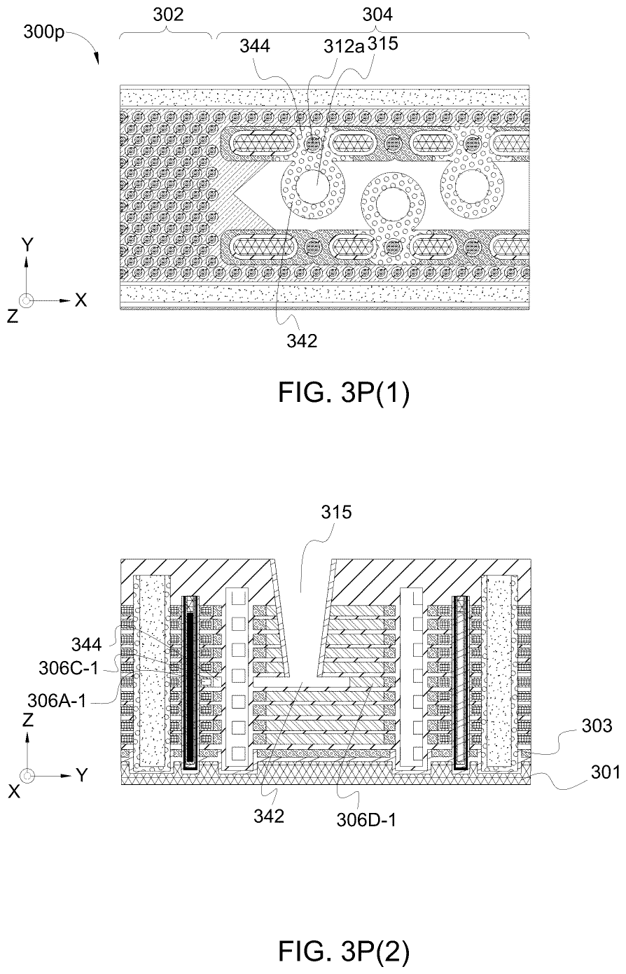

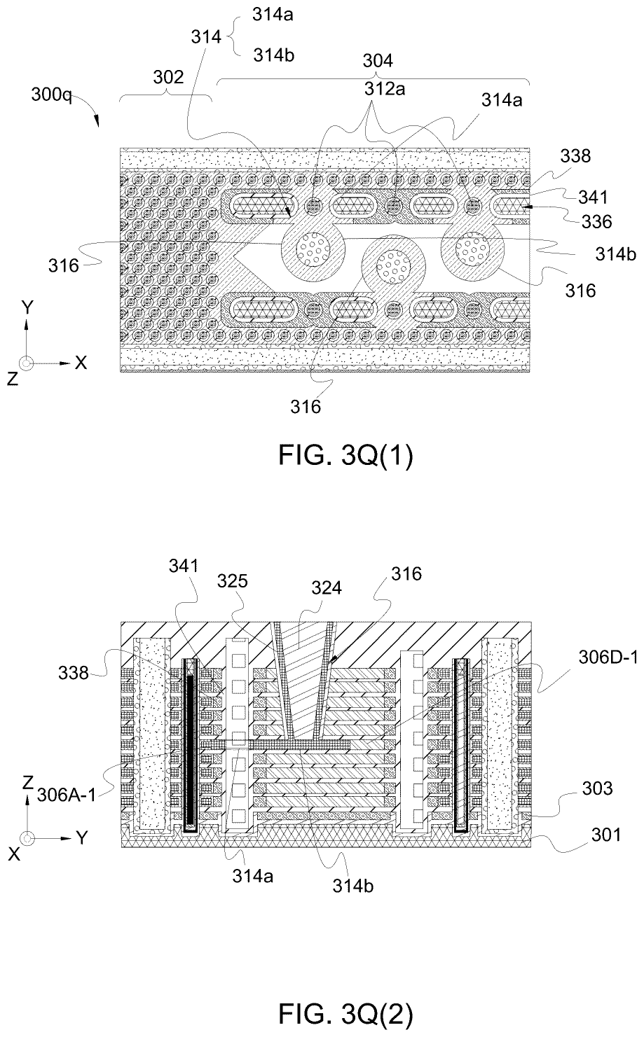

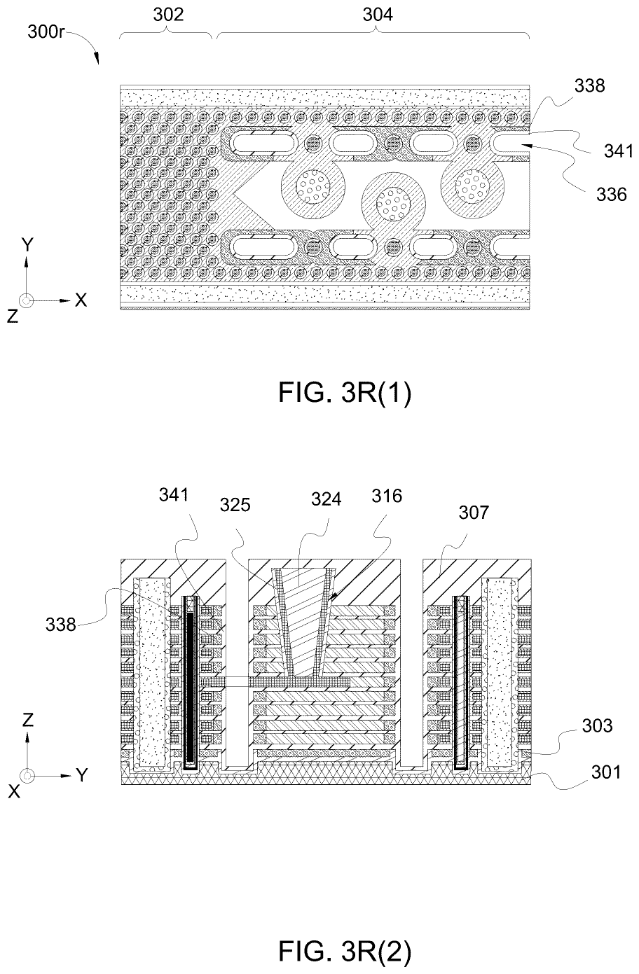

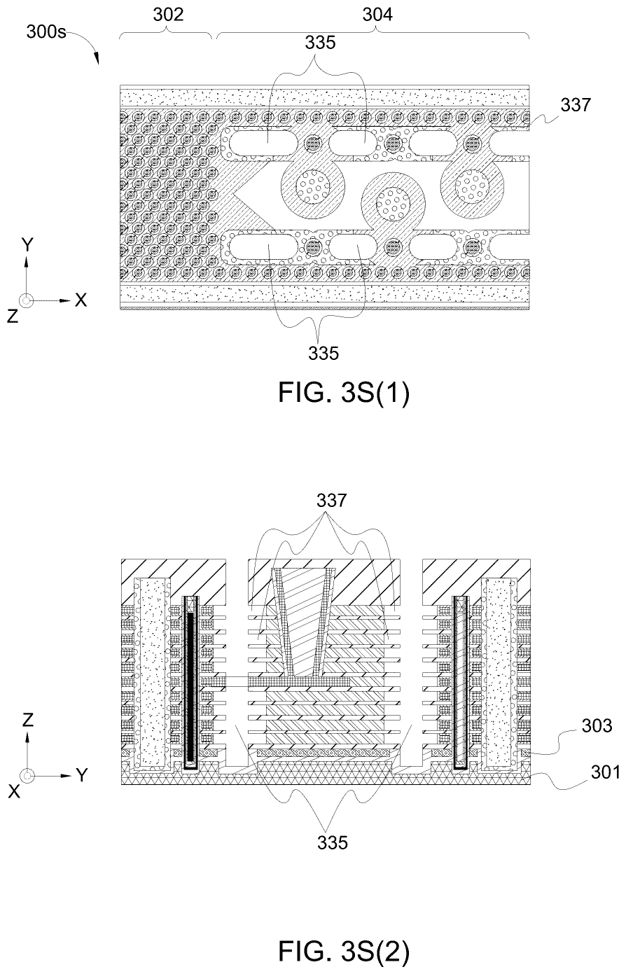

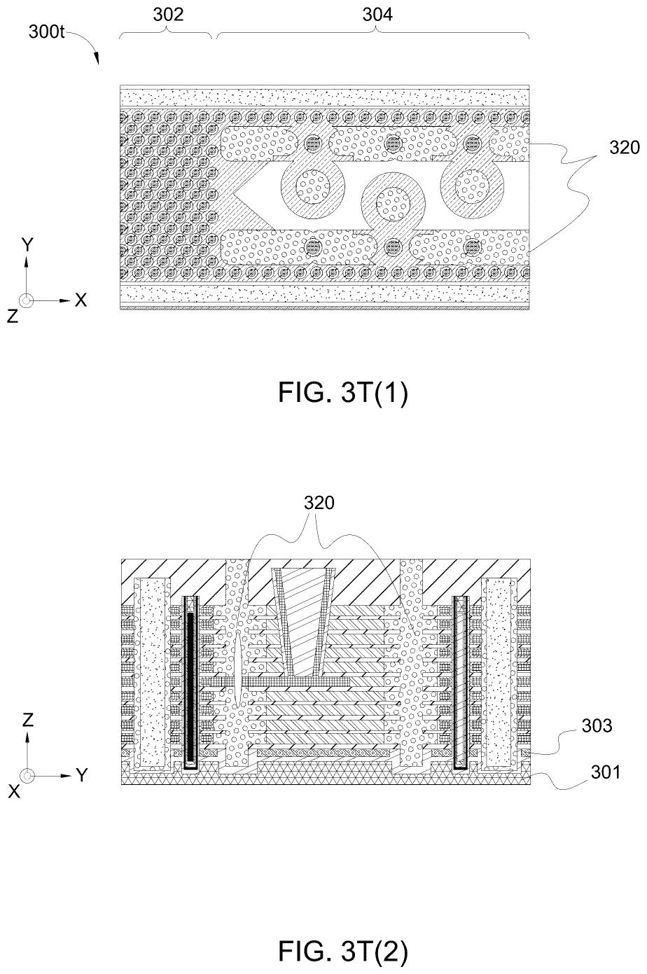

FIGS. 3A(1)-3T(2) illustrate an example process of fabricating a semiconductor device, such as the semiconductor device 100 as illustrated in FIGS. 1A-1D or the semiconductor device 200 as illustrated in FIGS. 2A-2B. FIGS. 3A(1), 3B(1), . . . , and 3T(1) show top views of example semiconductor structures at various stages of the fabrication process. FIGS. 3A(2), 3B(2), . . . , and 3T(2) show cross-sectional views (e.g., along a cut line at the same location as the cut line AA′ of FIG. 1A) of example semiconductor structures at various stages of the fabrication process.

As shown in FIGS. 3A(1)-3A(2), a semiconductor structure 300a is formed. FIG. 3A(1) illustrates that the semiconductor structure 300a can have an array region 302 and a connection region 304 adjacent to the array region 302 (e.g., along the X direction). The array region 302 can be an example of the array region 102 of the semiconductor device 100 of FIG. 1A, and the connection region 304 can be an example of the connection region 104 of the semiconductor device 100. The semiconductor structure 300a includes a substrate 301 and a stack 305 of sacrificial layers 306D (also referred to as dielectric layers) and isolating layers 306B provided over the substrate 301. The stack 305 can extend across the array region 302 and the connection region 304. The sacrificial layers 306D and the isolating layers 306B can alternate with each other along the vertical direction (e.g., the Z direction). The substrate 301 and each of the sacrificial layers 306D and isolating layers 306B can extend in the X-Y plane. The semiconductor structure 300a further includes a semiconductor layer 303 between the stack 305 and the substrate 301 along the Z direction. The semiconductor layer 303 can be made of a suitable semiconductor material (e.g., polysilicon). The semiconductor structure 300a can be formed by, for example, depositing the stack 305 of sacrificial layers 306D and isolating layers 306B over the semiconductor layer 303. The isolating layers 306B can include dielectric material, such as silicon oxide, silicon nitride, silicon oxynitride, or any combination thereof. In some implementations, the sacrificial layers 306D can include a dielectric material different from the dielectric material of the isolating layers 306B. For example, the isolating layers 306B can include silicon oxide, and the sacrificial layers 306D can include silicon nitride.

The semiconductor structure 300a includes one or more groups of gate line holes 317. Each group of gate line holes 317 includes gate line holes in the array region 302 and gate line holes in the connection region 304. Each group of gate line holes 317 are arranged in a line extending along the X direction and are spaced from one another along the line. The semiconductor structure 300a includes an array of channel holes 309 in the array region 302. The semiconductor structure 300a includes one or more groups of isolating holes 333, one or more groups of first dummy channel holes 311a, and one or more groups of second dummy channel holes 311b in the connection region 304. Each group of second dummy channel holes 311b are arranged in a line extending along the X direction. A group of isolating holes 333 and a group of first dummy channel holes 311a are arranged in a line extending along the X direction. The group of isolating holes 333 can be separated by the group of first dummy channel holes 311a along the X direction. For example, as shown in FIG. 3A(1), one of the first dummy channel holes 311a is between two adjacent isolating holes of the group of isolating holes 333 along the X direction. Each group of second dummy channel holes 311b can be arranged between a group of gate line holes 317 and a group of first dummy channel holes 311a along the Y direction. The one or more groups of gate line holes 317, the array of channel holes 309, the one or more groups of isolating holes 333, the one or more groups of first dummy channel holes 311a, and the one or more groups of second dummy channel holes 311b can extend through the stack 305 of sacrificial layers 306D and isolating layers 306B along the Z direction. In some implementations, the one or more groups of gate line holes 317, the array of channel holes 309, the one or more groups of isolating holes 333, the one or more groups of first dummy channel holes 311a, and the one or more groups of second dummy channel holes 311b are formed by a same etching process.

The semiconductor structure 300a can be formed by filling a filler material (which is also referred to as a sacrificial material such as polysilicon or carbon) into the one or more groups of gate line holes 317, the array of channel holes 309, the one or more groups of isolating holes 333, the one or more groups of first dummy channel holes 311a, and the one or more groups of second dummy channel holes 311b. A dielectric layer 307 (e.g., silicon oxide) can be deposited on top of the semiconductor structure 300a to cover the one or more groups of gate line holes 317, the array of channel holes 309, the one or more groups of isolating holes 333, the one or more groups of first dummy channel holes 311a, and the one or more groups of second dummy channel holes 311b. A planarization process, such as chemical mechanical polishing (CMP), can be performed to remove the excess dielectric material on top of the semiconductor structure 300a.

As shown in FIGS. 3B(1)-3B(2), a semiconductor structure 300b is formed by forming an array of channel structures 310 in the array of channel holes 309, first isolating structures 312a in the first dummy channel holes 311a, and second isolating structure 312b in the second dummy channel holes 311b. Openings can be formed to expose the filler material in the array of channel holes 309. The filler material in the array of channel holes 309 can be removed. The array of channel structures 310 can be formed by depositing a high-K layer, a memory film, a channel layer, and a core filler layer into each of the array of channel holes 309. The memory film can include a block layer, a charge trapping layer, and a tunneling layer. In some implementations, the channel layer can include silicon, such as amorphous silicon, polysilicon, or single crystalline silicon, the tunneling layer can include silicon oxide, silicon nitride, or any combination thereof, the blocking layer can include silicon oxide, silicon nitride, high-K dielectrics, or any combination thereof, and the charge trapping layer can include silicon nitride, silicon oxynitride, silicon, or any combination thereof. In some implementations, the first isolating structures 312a and the second isolating structure 312b can have similar structures as the channel structures 310. The first isolating structures 312a and the second isolating structure 312b can be referred to as dummy channel structures. In some implementations, the array of channel structures 310, the first isolating structures 312a, and the second isolating structure 312b can be formed by a same deposition process.

As shown in FIGS. 3C(1)-3C(2), a semiconductor structure 300c is formed by forming openings in the dielectric layer 307 to expose the filler material in the isolating holes 333 and removing the filler material in the isolating holes 333. New isolating holes 333 can be formed which includes the isolating holes 333 (e.g., in the semiconductor structure 300b) and the openings on top of the isolating holes 333.

FIGS. 3D(1)-3D(2) illustrate a semiconductor structure 300d including inner holes 335. The isolating holes 333 can be expanded, for example, by an etching process. Each inner hole 335 can be formed by connecting or merging adjacent isolating holes of the expanded isolating holes 333. As shown in FIG. 3D(1), the inner holes 335 and the first isolating structures 312a can alternate with each other along the X direction.

FIGS. 3E(1)-3E(2) illustrate a semiconductor structure 300e including tunnels 337 between the isolating layers 306B of the stack 305. The tunnels 337 can be formed by an etching process, which removes a portion of the sacrificial layers 306D of the stack 305 exposed by the inner holes 335. The tunnels 337 can extend along the X direction. The inner holes 335 and the first isolating structures 312a can extend through the tunnels 337 along the Z direction. In some implementations, protection structures 339a (e.g., poly oxidation) can be formed on bottoms (which can be in contact with the substrate 301) of the inner holes 335 to protect the substrate 301.

As shown in FIGS. 3F(1)-3F(2), a semiconductor structure 300f including outer layers 338 is formed. The outer layers 338 can be formed by depositing a semiconductor material (e.g., polysilicon) in the tunnels 337.

FIGS. 3G(1)-3G(2) illustrate a semiconductor structure 300g including one or more spacer layers 341. Each spacer layer 341 can be formed by depositing a dielectric material on inner surfaces of the outer layers 338. Alternatively, in some implementations, the inner holes 335 can be filled with the dielectric material, and the dielectric material in the inner holes 335 form structures similar to, or the same as, the inner structures 136 of FIGS. 2A-2B. In some instances, the dielectric material in the inner holes 335 and the outer layers 338 can form the isolating wall 120 of FIGS. 2A-2B.

As shown in FIGS. 3H(1)-3H(2), a semiconductor structure 300h is formed by filling a sacrificial material (e.g., carbon) into the inner holes 335. A new dielectric layer 307 can be formed by depositing a dielectric material (e.g., silicon oxide) on top of the semiconductor structure 300h to cover the inner holes 335 and performing a planarization process (e.g., CMP) to remove the excess dielectric material on top of the semiconductor structure 300h.

As shown in FIGS. 3I(1)-3I(2), a semiconductor structure 300i is formed by forming openings in the dielectric layer 307 to expose the filler material in the one or more groups of gate line holes 317 and removing the filler material in the one or more groups of gate line holes 317.

FIGS. 3J(1)-3J(2) illustrate a semiconductor structure 300j including one or more gate line spaces 319. Each gate line space 319 can be formed by expanding one group of gate line holes 317 (e.g., by an etching process) and connecting or merging the group of expanded gate line holes 317. In some implementations, protection structures 339b (e.g., poly oxidation) can be formed on bottoms (which can be in contact with the substrate 301) of the one or more gate line spaces 319 to protect the substrate 301.

FIGS. 3K(1)-3K(2) illustrate a semiconductor structure 300k including a space 321 formed by an etching process. For example, the etching process can include filling an etching solution into the gate line space 319. The space 321 is formed by removing the sacrificial layers 306D of the stack 305 in the array region 302 and portions of the sacrificial layers 306D of the stack 305 in the connection region 304 between each gate line space 319 and adjacent outer layers 338. The space 321 exposes ends of the outer layers 338.

FIGS. 3L(1)-3L(2) illustrate a semiconductor structure 300l including conductive layers 306A and liner layers 306C. Each conductive layer 306A includes a portion between the isolating layers 306B in the array region 302. The conductive layer 306A further includes another portion in the space 321 in the connection region 304 (e.g., a portion between the gate line space 319 and adjacent outer layers 338 along the Y direction in the connection region 304). In some implementations, each conductive layer 306A can be surrounded by a respective liner layer 306C. The conductive layer 306A can include a conductive material (e.g., W). The liner layer 306C can include a high-K dielectric material (e.g., Al₂O₃). The liner layers 306C and the conductive layers 306A can be formed, for example, by depositing (e.g., through the gate line spaces 319) the high-K dielectric material and the conductive material into the space 321. In some implementations, as shown in FIG. 3L(2), the conductive layers 306A can be connected by excess conductive material deposited on inner surfaces of the gate line spaces 319.

FIGS. 3M(1)-3M(2) illustrate a semiconductor structure 300m including one or more gate line structures 318, a stack 306 of alternating conductive layers 306A and isolating layers 306B, and a stack 308 of alternating dielectric layers 306D and isolating layers 306B. The semiconductor structure 300m is formed by removing the excess conductive material deposited on inner surfaces of the gate line spaces 319, thereby isolating the conductive layers 306A from each other. Each gate line structure 318 can include a filling structure 318a and a dielectric layer 318b surrounding the filling structure. The filling structure 318a can include a filler material (e.g., polysilicon), and the dielectric layer 318b can include a dielectric material (e.g., silicon oxide). The gate line structures 318 can be formed by depositing the dielectric material and the filler material into the gate line spaces 319.

The stack 306 includes the conductive layers 306A and the liner layers 306C in the array region 302 and the connection region 304. The stack 306 further includes portions of the isolating layers 306B between the conductive layers 306A along the Z direction in the array region 302 and the connection region 304. The stack 308 includes remaining portions of the sacrificial layers or dielectric layers 306D in the connection region 304 and portions of the isolating layers 306B between the sacrificial layers 306D along the Z direction in the connection region 304. The stack 306 can be an example of the stack 106 of the semiconductor device 100 of FIGS. 1A-1B. The stack 308 can be an example of the stack 108 of the semiconductor device 100 of FIGS. 1A-1B.

FIGS. 3N(1)-3N(2) illustrate a semiconductor structure 300n including contact holes 315 in the connection region 304. The contact holes 315 can be formed by one or more etching processes. Each contact hole 315 can extend from a top (e.g., a surface farther away from the substrate 301) of the semiconductor structure 300n through the dielectric layer 307 and to one of the sacrificial layers 306D of the stack 308. Each contact hole 315 can extend through at least a part of the stack 308 along the Z direction. For example, as shown in FIG. 3N(2), the contact hole 315 extends into the stack 308 along the Z direction and reaches a sacrificial layer 306D-1 of the stack 308. In some implementations, a contact spacer 327 can be deposited on an inner surface of the contact hole 315. The contact spacer 327 can protect the sacrificial layers 306D exposed by the contact hole 315 from being affected by an etching process. In some implementations, each contact hole 315 is aligned with one of the first isolating structures 312a along the Y direction. As shown in FIG. 3N(2), an outer layer 338-1 of the outer layers 338 is in contact with the sacrificial layer 306D-1 and a corresponding conductive layer 306A-1 of the conductive layers 306A along the Y direction. In some implementations, the outer layer 338-1 is connected to the conductive layer 306A-1 through a liner layer 306C-1 surrounding the conductive layer 306A-1.

FIGS. 3O(1)-3O(2) illustrate a semiconductor structure 300o including a first space 342. The first space 342 can be formed in the sacrificial layer 306D-1 by removing (e.g., through an etching process) a portion of the sacrificial layer 306D-1 that is in contact with the contact hole 315 (e.g., along the Z direction) to expose the outer layer 338-1.

FIGS. 3P(1)-3P(2) illustrate a semiconductor structure 300p including a second space 344. The second space 344 is connected to the first space 342 along the Y direction. The second space 344 can be formed by removing (e.g., through an etching process) a portion of the outer layer 338-1 to expose the liner layer 306C-1. The first isolating structure 312a can extend through the second space 344 along the Z direction. Although not shown in FIGS. 3P(1)-3P(2), the second space 344 can be further expanded by removing a portion of the liner layer 306C-1 to expose the conductive layer 306A-1.

FIGS. 3Q(1)-3Q(2) illustrate a semiconductor structure 300q including a connecting structure 314. The connecting structure 314 can include a portion 314a in the first space 342 and a portion 314b in the second space 344. The connection structure 314 can be formed by depositing a conductive material into the first space 342 and the second space 344 through the contact hole 315. The portion 314a of the connecting structure 314 can be similar to, or same as the portion 114a of FIG. 1C.

The semiconductor structure 300q further includes contact structures 316. As shown in FIG. 3Q(2), one of the contact structures 316 is connected to the portion 314b of the connecting structure 314 along the Z direction. Each contact structure 316 can include a first layer 324 and a second layer 325 surrounding and being in contact with the first layer 324. The first layer 324 and the second layer 325 can extend along the Z direction. The first layer 324 can include a dielectric material (e.g., silicon oxide). The second layer 125 can include a conductive material. The second layer 325 of the contact structure 316 can be formed by depositing the conductive material on an inner surface of the contact hole 315. The first layer 324 of the contact structure 316 can be formed by filling the contact hole 315 with the dielectric material.

The semiconductor structure 300q further includes one or more isolating walls 320. Each isolating wall 320 can include outer layers 338 spaced along the Z direction and the first isolating structures 312a that extend through the outer layers 338 along the Z direction. The isolating wall 320 further includes inner structures 336 that extend through the outer layers 338 along the Z direction. As shown in FIGS. 3Q(1)-3Q(2), each inner structure 336 can include the spacer layer 341 and a filler material or a sacrificial material surrounded by the spacer layer 341.

In some implementations, the isolation wall 320 can have different structures from the one as shown in FIGS. 3Q(1)-3Q(2). FIGS. 3R(1)-3T(2) illustrate example semiconductor structures having isolation walls with some alternative structures.

As shown in FIGS. 3R(1)-3R(2), a semiconductor structure 300r is formed by depositing a dielectric layer on top of the dielectric layer 207 to cover and isolate the contact structures 316. Forming the semiconductor structure 300r further includes removing the sacrificial material surrounded by the spacer layer 341 of the inner structure 336. In some implementations (not shown in FIGS. 3R(1)-3R(2)), a dielectric material can be filled into a space within the spacer layer 341 to form a semiconductor structure similar to, or the same as, the semiconductor device 200 of FIGS. 2A-2B.

As shown in FIGS. 3S(1)-3S(2), a semiconductor structure 300s is formed. The semiconductor structure 300s includes the inner holes 335 and the tunnels 337 reformed by removing the spacer layers 341 and the outer layers 338.

FIGS. 3T(1)-3T(2) illustrate a semiconductor structure 300t having the isolating walls 320. The isolating walls 320 are formed by filling a dielectric material to the inner holes 335 and the tunnels 337. As shown in FIGS. 3T(2), the inner structures 336 and the outer layers 338 of the isolating walls 320 are filled with the dielectric material. The semiconductor structure 300s is similar to, or same as the semiconductor device 100 of FIGS. 1A-1D. In some implementations, compared to the isolating wall 120 that has outer layers 138 made of a semiconductor material (e.g., as shown in FIGS. 2A-2B), the isolating walls 320 having a solid dielectric structure as shown in FIGS. 3T(1)-3T(2) can provide better insulation.

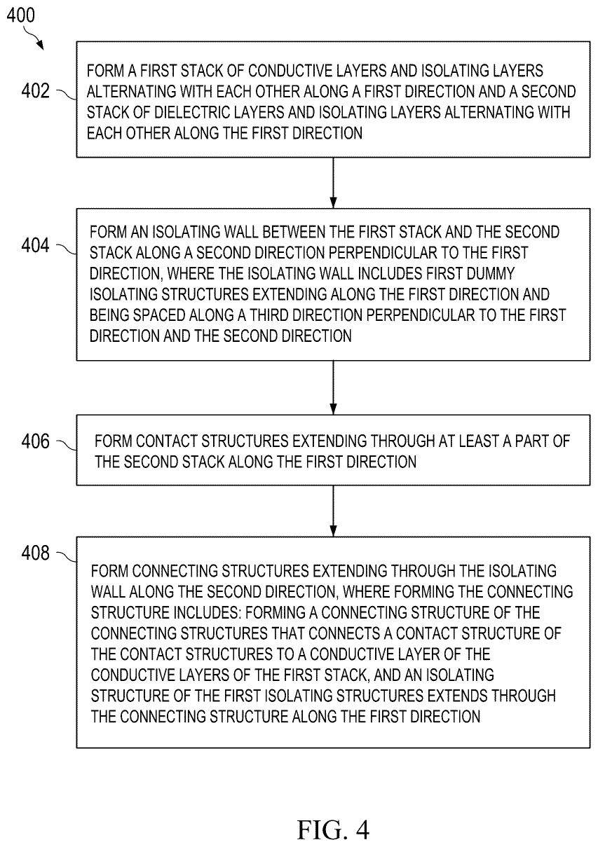

FIG. 4 illustrates a flow chart of an example process 400. The process 400 can be performed to form a semiconductor device (e.g., the semiconductor device 100 illustrated by FIGS. 1A-1D or the semiconductor device 200 illustrated by FIGS. 2A-2B). The process 400 can be described in view of FIGS. 3A(1)-3T(2). The process 400 can include one or more steps of the fabrication process of forming the semiconductor structures in FIGS. 3A(1)-3T(2). It is understood that the operations shown in process 400 are not exhaustive and that other operations can be performed as well before, after, or between any of the illustrated operations. Further, some of the operations may be performed simultaneously, or in a different order than shown in FIG. 4.

At operation 402, a first stack (e.g., the stack 306 of FIGS. 3M(1)-3M(2)) of conductive layers (e.g., conductive layers 306A) and isolating layers (e.g., isolating layers 306B) alternating with each other along a first direction (e.g., the Z direction) and a second stack (e.g., the stack 308 of FIGS. 3M(1)-3M(2)) of dielectric layers (e.g., sacrificial or dielectric layers 306D) and isolating layers (e.g., isolating layers 306B) alternating with each other along the first direction (e.g., the Z direction) are formed.

At operation 404, an isolating wall (e.g., the isolating wall 320 of FIGS. 3Q(1)-3Q(2) or the isolating wall 320 of FIGS. 3T(1)-3T(2)) is formed. The isolating wall is between the first stack and the second stack along a second direction (e.g., the Y direction) perpendicular to the first direction. The isolating wall includes first isolating structures (e.g., the first isolating structures 312a) extending along the first direction and being spaced along a third direction (e.g., the X direction) perpendicular to the first direction and the second direction.

At operation 406, contact structures (e.g., the contact structures 316 of FIGS. 3Q(1)-3T(2)) extending through at least a part of the second stack (e.g., the stack 308) along the first direction are formed.

At operation 408, connecting structures (e.g., the connecting structures 314 of FIGS. 3Q(1)-3T(2)) extending through the isolating wall (e.g., the isolating wall 320) along the second direction are formed. Forming the connecting structure includes forming a connecting structure of the connecting structures that connects a contact structure of the contact structures (e.g., the contact structures 316) to a conductive layer (e.g., the conductive layer 306A-1) of the conductive layers of the first stack. An isolating structure (e.g., first isolating structure 312a) of the first isolating structures extends through the connecting structure along the first direction.

In some implementations, the process 400 further includes forming a stack (e.g., the stack 305 of FIGS. 3A(1)-3A(2)) of dielectric layers (e.g., dielectric layers 306D) and isolating layers (e.g., the isolating layers 306B) alternating with each other along the first direction. The process 400 further includes forming an array of channel holes (e.g., the array of channel holes 309), isolating holes (e.g., the isolating holes 333), first dummy channel holes (e.g., the first dummy channel holes 311a), second dummy channel holes (e.g., the second dummy channel holes 311b), and gate line holes (e.g., the gate line holes 317) extending through the stack of dielectric layers and isolating layers along the first direction by a same etching process.

The array of channel holes is in an array region (e.g., the array region 302) of the semiconductor device, the isolating holes, the first dummy channel holes, and the second dummy channel holes are in a connection region (e.g., the connection region 304) of the semiconductor device. The gate line holes include gate line holes in the array region and gate line holes in the connection region. The isolating holes and the first dummy channel holes are arranged along a line extending in the third direction (e.g., as shown in FIGS. 3A(1)-3A(2)). One of the first dummy channel holes is between two adjacent isolating holes of the isolating holes along the third direction. The second dummy channel holes are arranged along a line extending in the third direction (e.g., as shown in FIGS. 3A(1)-3A(2)). The gate line holes are arranged along a line extending in the third direction (e.g., as shown in FIGS. 3A(1)-3A(2)). The second dummy channel holes are between the gate line holes and the first dummy channel holes along the second direction.

In some implementations, the process 400 further includes forming an array of channel structures (e.g., the channel structures 310 of FIGS. 3B(1)-3B(2)) in the array of channel holes (e.g., the channel holes 309), first isolating structures (e.g., the first isolating structure 312a) in the first dummy channel holes (e.g., the first dummy channel holes 311a), and second isolating structures (e.g., the second isolating structures 312b) in the second dummy channel holes (e.g., the second dummy channel holes 311b).

In some implementations, the process 400 further includes forming inner holes (e.g., the inner holes 335 of FIGS. 3D(1)-3D(2)) by expanding and connecting the isolating holes (e.g., the isolating holes 333 of FIGS. 3C(1)-3C(2)). The inner holes (e.g., the inner holes 335) and the first isolating structures (e.g., the first isolating structures 312a) alternate with each other along the third direction. In some implementations, the process 400 further includes forming tunnels (e.g., the tunnels 337 of FIGS. 3E(1)-3E(2)) between the isolating layers (e.g., the isolating layers 306B) of the stack (e.g., the stack 305) by removing a portion of the dielectric layers (e.g., the dielectric layers 306D) of the stack exposed by the inner holes. The tunnels extend along the third direction (e.g., as shown in FIG. 3E(1)), and the inner holes and the first isolating structures extend through the tunnels along the first direction (e.g., as shown in FIG. 3E(2)).

In some implementations, forming the isolating wall includes forming outer layers (e.g., the outer layers 338 of FIGS. 3G(1)-3G(2)) of the isolating wall by depositing a semiconductor material (e.g., polysilicon) in the tunnels and forming inner structures (e.g., the inner structures 336 of FIGS. 3R(1)-3R(2)) of the isolating wall by depositing a dielectric material (e.g., silicon oxide) into the inner holes (e.g., the inner holes 335). In some implementations, the process 400 further includes forming a gate line space (e.g., the gate line space 319 of FIGS. 3J(1)-3J(2)) by expanding the gate line holes (e.g., the gate line holes 317 of FIGS. 3I(1)-3I(2)). The gate line space includes the expanded gate line holes connected with each other along the third direction.

In some implementations, forming the first stack of conductive layers and isolating layers and the second stack of dielectric layers and isolating layers includes replacing (e.g., as described with reference to FIGS. 3K(1)-3M(2)) the dielectric layers of the stack in the array region and the dielectric layers of the stack in the connection region between the gate line space and the isolating wall with conductive layers (e.g., the conductive layer 306A of FIGS. 3M(1)-3M(2)). The first stack (e.g., the stack 306) includes the conductive layers (e.g., the conductive layers 306A) and the isolating layers (e.g., the isolating layers 306B) in the array region (e.g., the array region 302) and the conductive layers (e.g., the conductive layers 306A) and the isolating layers (e.g., the isolating layers 306B) in the connection region (e.g., the connection region 304) between the gate line space (e.g., the gate line space 319) and the isolating wall (e.g., the isolating wall 320). The second stack (e.g., the stack 308) includes a remaining portion of the dielectric layers (e.g., the dielectric layers 306D) of the stack (e.g., the stack 205) and the isolating layers (e.g., the isolating layers 306B) of the stack in the connection region. The conductive layer (e.g., the conductive layer 306A-1 of FIG. 3N(2)) of the conductive layers of the first stack is surrounded by a liner layer (e.g., the liner layer 306C-1 of FIG. 3N(2)).

In some implementations, the process 400 further includes forming a gate line structure (e.g., the gate line structure 318 of FIGS. 3M(1)-3M(2)) by filling the gate line space (e.g., the gate line space 319) with the semiconductor material (e.g., polysilicon).

In some implementations, the process 400 further includes forming a contact hole (e.g., the contact hole 315 of FIGS. 3N(1)-3N(2)) in the connection region. The contact hole extends into the second stack (e.g., the stack 308) along the first direction and reaches a dielectric layer (e.g., the dielectric layer 306D-1) of the dielectric layers of the second stack. The contact hole is aligned with the isolating structure (e.g., the first isolating structure 312a) along the second direction, an outer layer (e.g., the outer layer 338-1) of the outer layers of the isolating wall is in contact with the dielectric layer (e.g., the dielectric layer 306D-1) and the conductive layer (e.g., the conductive layer 306A-1) along the second direction.

In some implementations, the process 400 further includes forming a first space (e.g., the first space 342 of FIGS. 3O(1)-3O(2)) in the dielectric layer by removing a portion of the dielectric layer that is in contact with the contact hole (e.g., along the Z direction) to expose the outer layer (e.g., the outer layer 338-1).

In some implementations, the process 400 further includes forming a second space (e.g., the second space 344 of FIGS. 3P(1)-3P(2)) by removing a portion of the outer layer (e.g., the outer layer 338-1) to expose the liner layer (e.g., the liner layer 306C-1) in contact with the conductive layer (e.g., the conductive layer 306A-1) along the second direction.

In some implementations, the process 400 further includes expanding the second space by removing a portion of the liner layer (e.g., the liner layer 306C-1) to expose the conductive layer (e.g., the conductive layer 306A-1).

In some implementations, forming the connecting structure (e.g., the connecting structure 314 of FIGS. 3Q(1)-3Q(2)) includes forming the connecting structure in the first space (e.g., the first space 342) and the second space (e.g., the second space 344) by depositing a conductive material into the first space and the second space through the contact hole (e.g., the contact hole 315). Forming the contact structure (e.g., the contact structure 316) includes forming a first layer (e.g., the first layer 324) of the contact structure by depositing the conductive material on an inner surface of the contact hole and forming a second layer (e.g., the second layer 325) of the contact structure by filling the contact hole with a dielectric material.

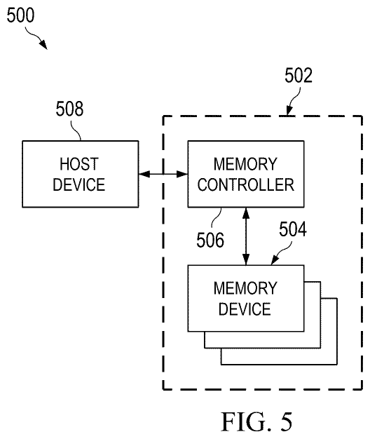

FIG. 5 illustrates a block diagram of an example system 500. The system 500 can have one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 5, the system 500 can include a host device 508 and a memory system 502 having one or more memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more memory devices 504.

A memory device 504 can be any memory device disclosed in the present disclosure, such as a memory device (e.g., a NAND Flash memory) as shown in FIGS. 1A-1D or a memory device as shown in FIGS. 2A-2B. Memory controller 506 (a.k.a., a controller circuit) is coupled to memory device 504 and host device 508. Consistent with implementations of the present disclosure, memory device 504 can include a plurality of conductive interconnections through a cover layer that are in contact with conductive pads in a conductive pad layer, and memory controller 506 can be coupled to memory device 504 through at least one of the plurality of conductive interconnections. Memory controller 506 is configured to control memory device 504. For example, memory controller 506 may be configured to operate a plurality of channel structures via word lines. Memory controller 506 can manage data stored in memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of memory device 504, such as read, erase, and program (or write) operations. Memory controller 506 can also be configured to manage various functions with respect to the data stored or to be stored in memory device 504 including, but not limited to bad-block management, garbage collection, logical-to-physical address conversion, wear leveling, etc. In some implementations, memory controller 506 is further configured to process error correction codes (ECCs) with respect to the data read from or written to memory device 504. Any other suitable functions may be performed by memory controller 506 as well, for example, formatting memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g.,.+−.10%,.+−. 20%, or .+−. 30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first stack of conductive layers and isolating layers alternating with each other along a first direction;
a second stack of dielectric layers and isolating layers alternating with each other along the first direction;
an isolating wall between the first stack and the second stack along a second direction perpendicular to the first direction, wherein the isolating wall comprises first isolating structures extending along the first direction and being spaced along a third direction perpendicular to the first direction and the second direction;
contact structures extending through at least a part of the second stack along the first direction; and
connecting structures extending through the isolating wall along the second direction, wherein a connecting structure of the connecting structures connects a contact structure of the contact structures to a conductive layer of the conductive layers of the first stack, and an isolating structure of the first isolating structures extends through the connecting structure along the first direction.

2. The semiconductor device of claim 1, further comprising:
a gate line structure extending along the third direction, wherein the first stack is between the gate line structure and the isolating wall along the second direction.

3. The semiconductor device of claim 1, further comprising:
second isolating structures extending through the first stack along the first direction, wherein at least one of the second isolating structures is adjacent to the connecting structure along the second direction.

4. The semiconductor device of claim 1, wherein the isolating wall further comprises:
inner structures extending along the first direction and being spaced along the third direction, wherein the inner structures and the first isolating structures alternate with each other along the third direction; and
outer layers extending along the third direction and being spaced along the first direction, wherein the inner structures and the first isolating structures extend through the outer layers along the first direction.

5. The semiconductor device of claim 4, wherein the inner structures comprise a dielectric material, and the outer layers comprise a semiconductor material.

6. The semiconductor device of claim 4, wherein the inner structures and the outer layers comprise a same dielectric material.

7. The semiconductor device of claim 1, wherein along the third direction, a first size of the connecting structure at a first location is smaller than a second size of the connecting structure at a second location, the first location being closer to a center of the isolating structure than the second location along the second direction.

8. The semiconductor device of claim 1, wherein the semiconductor device comprises an array region and a connection region adjacent to the array region in the second direction, the second stack is in the connection region, and the semiconductor device comprises an array of channel structures in the array region.

9. The semiconductor device of claim 1, comprising a first semiconductor structure and a second semiconductor structure bonded together, wherein the first semiconductor structure comprises the first stack, the second stack, the isolating wall, the contact structures, and the connecting structure, and wherein the second semiconductor structure comprises a peripheral circuit coupled to the first semiconductor structure and configured to control the semiconductor device.

10. A semiconductor device, comprising:
a first stack of conductive layers and isolating layers alternating with each other along a first direction;
a second stack of dielectric layers and isolating layers alternating with each other along the first direction;
an isolating wall between the first stack and the second stack along a second direction perpendicular to the first direction;
contact structures extending through at least a part of the second stack along the first direction; and
connecting structures extending through the isolating wall along the second direction, wherein along a third direction perpendicular to the first direction and the second direction, a first size of a connecting structure of the connecting structures at a first location is smaller than a second size of the connecting structure at a second location, and wherein the first location being closer to a center of the isolating wall than the second location along the second direction.

11. The semiconductor device of claim 10, wherein the connecting structure connects a contact structure of the contact structures to a conductive layer of the conductive layers of the first stack.

12. The semiconductor device of claim 10, wherein the isolating wall comprises isolating structures extending along the first direction and being spaced along a third direction perpendicular to the first direction and the second direction, and an isolating structure of the isolating structures extends through the connecting structure along the first direction.

13. The semiconductor device of claim 12, wherein the isolating wall further comprises:
inner structures extending along the first direction and being spaced along the third direction, wherein the inner structures and the isolating structures alternate with each other along the third direction; and
outer layers extending along the third direction and being spaced along the first direction, wherein the inner structures and the isolating structures extend through the outer layers along the first direction.

14. A method of forming a semiconductor device, comprising:
forming a first stack of conductive layers and isolating layers alternating with each other along a first direction and a second stack of dielectric layers and isolating layers alternating with each other along the first direction;
forming an isolating wall between the first stack and the second stack along a second direction perpendicular to the first direction, wherein the isolating wall comprises first isolating structures extending along the first direction and being spaced along a third direction perpendicular to the first direction and the second direction;
forming contact structures extending through at least a part of the second stack along the first direction; and
forming connecting structures extending through the isolating wall along the second direction, wherein forming the connecting structures comprises:
forming a connecting structure of the connecting structures that connects a contact structure of the contact structures to a conductive layer of the conductive layers of the first stack, and an isolating structure of the first isolating structures extends through the connecting structure along the first direction.

15. The method of claim 14, further comprising:
forming a stack of dielectric layers and isolating layers alternating with each other along the first direction;
forming an array of channel holes, isolating holes, first dummy channel holes, second dummy channel holes, and gate line holes extending through the stack of dielectric layers and isolating layers along the first direction by a same etching process, wherein:
the array of channel holes is in an array region of the semiconductor device, the isolating holes, the first dummy channel holes, and the second dummy channel holes are in a connection region of the semiconductor device, and the gate line holes comprise gate line holes in the array region and gate line holes in the connection region;
the isolating holes and the first dummy channel holes are arranged along a line extending in the third direction, wherein one of the first dummy channel holes is between two adjacent isolating holes of the isolating holes along the third direction;
the second dummy channel holes are arranged along a line extending in the third direction;
the gate line holes are arranged along a line extending in the third direction; and
the second dummy channel holes are between the gate line holes and the first dummy channel holes along the second direction, and
forming an array of channel structures in the array of channel holes, first isolating structures in the first dummy channel holes, and second isolating structures in the second dummy channel holes.

16. The method of claim 15, further comprising:
forming inner holes by expanding and connecting the isolating holes, wherein the inner holes and the first isolating structures alternate with each other along the third direction; and
forming tunnels between the isolating layers of the stack by removing a portion of the dielectric layers of the stack exposed by the inner holes, wherein the tunnels extend along the third direction, and the inner holes and the first isolating structures extend through the tunnels along the first direction.

17. The method of claim 16, wherein forming the isolating wall comprises:
forming outer layers of the isolating wall by depositing a semiconductor material in the tunnels; and
forming inner structures of the isolating wall by depositing a dielectric material into the inner holes,
and the method further comprises:
forming a gate line space by expanding the gate line holes, wherein the gate line space comprises the expanded gate line holes connected with each other along the third direction.

18. The method of claim 17, wherein forming the first stack of conductive layers and isolating layers and the second stack of dielectric layers and isolating layers comprises:
replacing the dielectric layers of the stack in the array region and the dielectric layers of the stack in the connection region between the gate line space and the isolating wall with conductive layers, wherein the first stack comprises the conductive layers and the isolating layers in the array region and the conductive layers and the isolating layers in the connection region between the gate line space and the isolating wall, the second stack comprises a remaining portion of the dielectric layers of the stack and the isolating layers of the stack in the connection region, and the conductive layer of the conductive layers of the first stack is surrounded by a liner layer.

19. The method of claim 18, further comprising:
forming a gate line structure by filling the gate line space with the semiconductor material;
forming a contact hole in the connection region, wherein the contact hole extends into the second stack along the first direction and reaches a dielectric layer of the dielectric layers of the second stack, the contact hole is aligned with the isolating structure along the second direction, an outer layer of the outer layers of the isolating wall is in contact with the dielectric layer and the conductive layer along the second direction;
forming a first space in the dielectric layer by removing a portion of the dielectric layer that is in contact with the contact hole to expose the outer layer;
forming a second space by removing a portion of the outer layer to expose the liner layer in contact with the conductive layer along the second direction; and
expanding the second space by removing a portion of the liner layer to expose the conductive layer.

20. The method of claim 19, wherein forming the connecting structure comprises forming the connecting structure in the first space and the second space by depositing a conductive material into the first space and the second space through the contact hole, and wherein forming the contact structure comprises:
forming a first layer of the contact structure by depositing the conductive material on an inner surface of the contact hole; and
forming a second layer of the contact structure by filling the contact hole with a dielectric material.
